(19) United States
(12) Patent Application Publication
(10) Pub. No.: US 2026/0059780 A1
(43) Pub. Date: Feb. 26, 2026

(54) SEMICONDUCTOR DEVICE AND METHOD FOR FABRICATING THE SAME

(71) Applicant: SK hynix Inc., Gyeonggi-do (KR)

(72) Inventor: Dong Il SONG, Gyeonggi-do (KR)

(21) Appl. No.: 19/064,692

(22) Filed: Feb. 27, 2025

(30) Foreign Application Priority Data
Aug. 23, 2024 (KR) 10-2024-0113560

(51) Int. Cl. H10D 30/01; H01L 21/768; H01L 23/00; H01L 25/16; H10B 12/00; H10B 80/00; H10D 30/00; H10D 62/10; H10D 80/30

(52) U.S. Cl. CPC H10D 30/0191; H01L 21/76837; H10B 12/05; H10B 12/488; H10D 30/0197; H10D 30/502; H10D 62/121; H01L 24/08; H01L 24/80; H01L 25/16; H01L 2224/08145; H01L 2224/80895; H01L 2224/80896; H01L 2924/1431; H10B 12/50; H10B 80/00; H10D 80/30

(57) ABSTRACT

A semiconductor device may include high-integrated memory cells, and a method for fabricating the semiconductor device may include forming a plurality of preliminary nano sheets disposed with first horizontal gaps therebetween over a substrate, forming a spacer layer surrounding portions of the preliminary nano sheets and defines second horizontal gaps between the preliminary nano sheets, forming gap-fill layers that fill the second horizontal gaps of the spacer layer, forming inter-cell dielectric layers on the gap-fill layers and the spacer layer, horizontally recessing the gap-fill layers and the spacer layer and forming a linear surrounding recess, and forming a conductive line horizontally extending while surrounding portions of the preliminary nano sheets in the linear surrounding recess.

### CROSS-REFERENCE TO RELATED APPLICATIONS

The present application claims priority under 35 U.S.C 119(a) to Korean Patent Application No. 10-2024-0113560, filed on Aug. 23, 2024, which is incorporated herein by reference in its entirety.

### BACKGROUND

### 1. Field

Various embodiments of the present disclosure relate to a semiconductor device, and more particularly, to a semiconductor device including three-dimensional (3D) memory cells, and a method for fabricating the semiconductor device.

### 2. Description of the Related Art

Recently, in order to cope with the trend of large capacity and miniaturization of a memory device, a three-dimensional (3D) memory device in which a plurality of memory cells are stacked has been proposed.

### SUMMARY

Embodiments of the present disclosure are directed to a semiconductor device including high-integrated memory cells, and a method for fabricating the semiconductor device.

In accordance with an embodiment of the present disclosure, a method for fabricating a semiconductor device may include forming a plurality of preliminary nano sheets disposed with first horizontal gaps therebetween over a substrate; forming a spacer layer surrounding portions of the preliminary nano sheets and defining second horizontal gaps between the preliminary nano sheets; forming gap-fill layers that fill the second horizontal gaps of the spacer layer; forming inter-cell dielectric layers on the gap-fill layers and the spacer layer; horizontally recessing the gap-fill layers and the spacer layer and forming a linear surrounding recess; and forming a conductive line horizontally extending while surrounding portions of the preliminary nano sheets in the linear surrounding recess.

In accordance with an embodiment of the present disclosure, a method for fabricating a semiconductor device may include forming an alternating stack by alternately stacking a plurality of first mold layers with a plurality of second mold layers over a substrate; forming a linear opening in the alternating stack; recessing the first mold layers from the linear opening; selectively recessing the second mold layers from the linear opening and forming narrow sheets of a plurality of preliminary nano sheets that are horizontally spaced apart from each other with first horizontal gaps therebetween; forming a spacer layer that surrounds the narrow sheets of the preliminary nano sheets and defines second horizontal gaps; forming gap-fill layers that fill the second horizontal gaps of the spacer layer; forming inter-cell dielectric layers on the gap-fill layers and the spacer layer; and replacing the gap-fill layers and portions of the spacer layer with a horizontal conductive line.

In accordance with an embodiment of the present disclosure, a semiconductor device may include a vertical stack in which inter-cell dielectric layers are alternately stacked with nano sheets; first conductive lines coupled to first edges of the nano sheets and vertically oriented in a stacking direction of the vertical stack; second conductive lines including inner surfaces that face the nano sheets and outer surfaces that face the inter-cell dielectric layers, and horizontally oriented in a direction crossing the stacking direction of the vertical stack; nano sheet dielectric layers formed between inner surfaces of the second conductive lines and the nano sheets and formed between outer surfaces of the second conductive lines and the inter-cell dielectric layers; and data storage elements coupled to second edges of the nano sheets, respectively.

In accordance with an embodiment of the present disclosure, a semiconductor device may include horizontally oriented nano sheets spaced apart from each other with a gap at the same horizontal level; vertically oriented first conductive lines coupled to first edges of the horizontally oriented nano sheets, respectively; second conductive lines horizontally extending while surrounding the horizontally oriented nano sheets; data storage elements coupled to second edges of the nano sheets, respectively, wherein the second conductive lines may each include surrounding bodies that surround portions of the horizontally oriented nano sheets and surrounding merged portions between the surrounding bodies.

In accordance with an embodiment of the present disclosure, a semiconductor device may include an array of memory cells vertically stacked, wherein the array may include horizontally oriented switching elements, vertically oriented first conductive lines, and horizontally oriented data storage elements, and the horizontally oriented switching elements may include nano sheets and horizontally oriented second conductive lines, and the nano sheets may include first doped regions, second doped regions, and channels between the first doped regions and the second doped regions. The horizontally oriented second conductive lines may have a gate-all-around structure, and the horizontally oriented second conductive lines may surround all surfaces of the channels. The horizontally oriented second conductive lines may include surrounding bodies that surround the channels and surrounding merged portions between the surrounding bodies.

In accordance with an embodiment of the present disclosure, a semiconductor device may include an array of memory cells vertically stacked, wherein the array may include horizontally oriented nano sheets, vertically oriented first conductive lines, and horizontally oriented storage nodes, and the horizontally oriented nano sheets may include first doped regions, second doped regions, and channels between the first doped regions and the second doped regions. The horizontally oriented second conductive lines may include surrounding bodies that surround the channels and surrounding merged portions between the surrounding bodies. The horizontally oriented second conductive lines may have a gate-all-around structure.

In accordance with an embodiment of the present disclosure, a semiconductor device may include an array of memory cells vertically stacked, wherein the array may include horizontally oriented nano sheets including first doped regions, second doped regions, and horizontally oriented channels between the first doped regions and the second doped regions, vertically oriented first conductive lines, and horizontally oriented data storage elements, and the horizontally oriented second conductive lines may include surrounding bodies that surround the channels and surrounding merged portions between the surrounding bodies. The horizontally oriented second conductive lines may have a gate-all-around structure.

In accordance with an embodiment of the present disclosure, a semiconductor device may include a horizontal arrangement of nano sheets; and a horizontal conductive line that surrounds the horizontal arrangement of the nano sheets, wherein the horizontal conductive line may include surrounding bodies that surround the nano sheets and surrounding merged portions that fill horizontal gaps between the nano sheets.

In accordance with an embodiment of the present disclosure, a semiconductor device may include a stack with alternating inter-cell dielectric layers and nano sheets; first conductive lines coupled to first edges of the nano sheets; second conductive lines disposed between the nano sheets and the inter-cell dielectric layers; nano sheet dielectric layers disposed to separate the second conductive lines from the nano sheets and also separate the second conductive lines from the inter-cell dielectric layers; and data storage elements coupled to second edges of the nano sheets.

### BRIEF DESCRIPTION OF THE DRAWINGS

FIG. 1A is a schematic perspective view illustrating a memory cell in accordance with an embodiment of the present disclosure.

FIG. 1B is a schematic cross-sectional view of the memory cell illustrated in FIG. 1A.

FIG. 2 is a schematic perspective view illustrating a semiconductor device in accordance with an embodiment of the present disclosure.

FIG. 3 is a schematic plan view illustrating a semiconductor device in accordance with an embodiment of the present disclosure.

FIG. 4A is a cross-sectional view of the semiconductor device taken along line A-A′ of FIG. 3.

FIG. 4B is a cross-sectional view of the semiconductor device taken along line B-B′ of FIG. 3.

FIGS. 5A to 22B illustrate various views of a semiconductor device formed utilizing a method for fabricating the semiconductor device in accordance with an embodiment of the present disclosure.

FIGS. 23A and 23B are schematic cross-sectional views of a semiconductor device in accordance with an embodiment of the present disclosure.

FIGS. 24A and 24B illustrate various views illustrating a stack assembly in accordance with an embodiment of the present disclosure.

### DETAILED DESCRIPTION

Various embodiments of the present disclosure may be described herein with reference to cross-sectional views, plan views and block diagrams, which are ideal schematic views of a semiconductor device. It is noted that the structures of the drawings may be modified by fabricating techniques and/or tolerances. The embodiments of the present disclosure are not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the embodiments of the present disclosure.

The following embodiment relates to three-dimensional memory cells with memory cells vertically stacked for increasing the memory cell density and reducing parasitic capacitance.

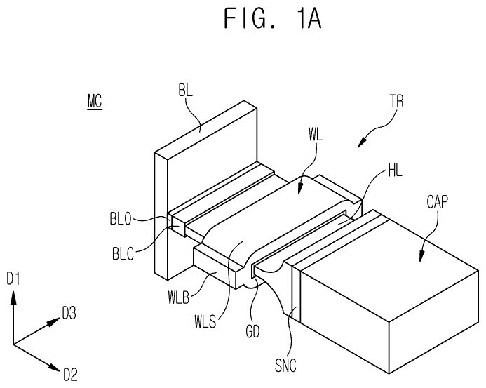

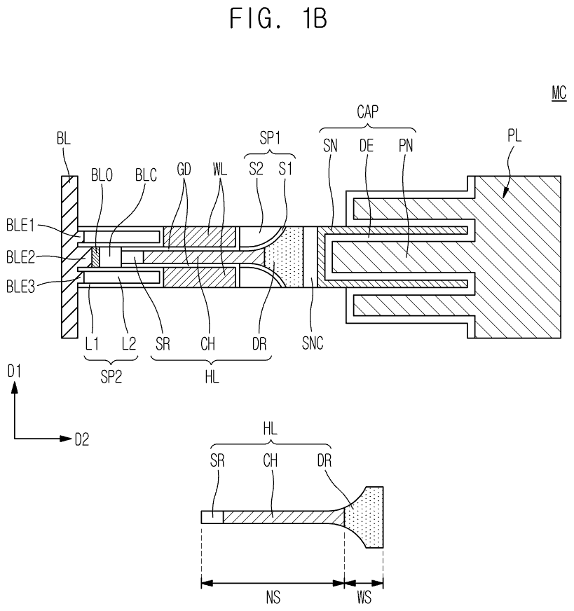

FIG. 1A is a schematic perspective view illustrating a memory cell MC in accordance with an embodiment of the present disclosure. FIG. 1B is a schematic cross-sectional view of the memory cell MC illustrated in FIG. 1A.

Referring to FIGS. 1A and 1B, the memory cell MC may include a first conductive line BL, a switching element TR, and a data storage element CAP.

The first conductive line BL may be vertically oriented in a first direction D1. The first conductive line BL may include a bit line. The first conductive line BL may be referred to as a “vertical conductive line”, a “vertically-oriented bit line”, a “vertically-extending bit line”, or a “pillar-shaped bit line”. The first conductive line may have a rectangular cross-section with a length (i.e., the larger dimension of the rectangle) extending along a third direction D3, and a width (i.e., the shorter dimension of the rectangle) extending along a second direction D2. The first direction D1 may be vertical to the plane of the second and third directions D2, and D3. The first conductive line BL may include a conductive material. The first conductive line BL may include a silicon-based material, a metal-based material, or a combination thereof. The first conductive line BL may include polysilicon, metal such as tungsten, metal nitride such as titanium nitride, metal silicide, or a combination thereof. For example, the first conductive line BL may include a titanium nitride/tungsten stack (TiN/W) in which titanium nitride and tungsten are sequentially stacked.

The switching element TR has a function of controlling the voltage or current supply to the data storage element CAP during a data write operation and a data read operation performed onto the data storage element CAP. The switching element TR may include a nano sheet HL, a nano sheet dielectric layer GD, and a second conductive line WL. The second conductive line WL may include a horizontal conductive line or a horizontal word line, and the nano sheet HL may include an active layer. The switching element TR may include a transistor, and in this case, the second conductive line WL may serve as a gate electrode. The switching element TR may also be referred to as a “nano sheet transistor”, an “access element” or a “selection element”. The second conductive line WL may be referred to as a “horizontal gate electrode”or a “horizontal word line”.

The nano sheet HL may extend in a second direction D2 that intersects with the first direction D1. The second conductive line WL may extend in a third direction D3 that intersects with the first direction D1 and the second direction D2. The first direction D1 may be a vertical direction, the second direction D2 may be a first horizontal direction, and the third direction D3 may be a second horizontal direction. The nano sheet HL may extend in the first horizontal direction, i.e., the second direction D2, and the second conductive line WL may extend in the second horizontal direction, i.e., the third direction D3. The nano sheet HL may be referred to as a “horizontal layer”.

The nano sheet HL may include a channel CH, a first doped region SR between the channel CH and the first conductive line BL, and a second doped region DR between the channel CH and the data storage element CAP. The first doped region SR may be electrically coupled to the first conductive line BL, and the second doped region DR may be electrically coupled to the data storage element CAP. The height of the second doped region DR in the first direction D1 may be greater than the heights of the first doped region SR and the channel CH in the first direction D1. The length of the second doped region DR in the second direction D2 may be less than that of the channel CH in the second direction D2. The lengths of the first doped region SR, the channel CH and the second doped region DR in the third direction D3 may be equal to one another.

The nano sheet HL may include a first region NS and a second region WS that are horizontally disposed in the second direction D2. The second region WS may extend from the first region NS. The second region WS may have a thickness that gradually increases in the second direction D2 from the first region NS toward the data storage element CAP between the first region NS and the data storage element CAP. An average vertical height or thickness of the second region WS in the first direction D1 may be greater than that of the first region NS. Hereinafter, the first region NS is referred to as a “narrow sheet”, and the second region WS is referred to as a “wide sheet”.

The narrow sheet NS may have a flat plate shape. The wide sheet WS may have a fan-like shape. The wide sheet WS may have a thickness that gradually increases in the second direction D2. The narrow sheet NS may be referred to as a “flat plate-shaped sheet”, and the wide sheet WS may be referred to as a “fan-like shaped sheet”. A boundary portion between the narrow sheet NS and the wide sheet WS may have a curvature.

The first doped region SR and the channel CH may be disposed in the narrow sheet NS. The second doped region DR may be disposed in the wide sheet WS. The channel CH formed in the narrow sheet NS may be referred to as a “narrow channel” or a “flat channel”. One side of the wide sheet WS contacting the data storage element CAP and one side of the second doped region DR may each have a flat side shape.

In an embodiment, a portion of the second doped region DR may extend to be disposed in the narrow sheet NS. The second doped region DR may include a thick portion disposed in the wide sheet WS and a thin portion disposed in the narrow sheet NS.

A horizontal length of the wide sheet WS in the second direction D2 may be less than that of the narrow sheet NS. The narrow sheet NS may be referred to as a “long sheet”, and the wide sheet WS may be referred to as a “short sheet”.

The nano sheet HL may include a semiconductive material. For example, the nano sheet HL may include polysilicon, monocrystalline silicon, germanium, or silicon-germanium. In an embodiment, the nano sheet HL may include an oxide semiconductor material. For example, the oxide semiconductor material may include indium gallium zinc oxide (IGZO), indium tin zinc oxide (InSnZnO), zinc, tin oxide (ZnSnO), or a combination thereof. In an embodiment, the nano sheet HL may include conductive metal oxide. In an embodiment, the nano sheet HL may include a two-dimensional material, for example, molybdenum disulfide (MoS₂), tungsten disulfide (WS₂), or molybdenum diselenide (MoSe₂).

When the nano sheet HL is formed of the oxide semiconductor material, the channel CH may also be formed of the oxide semiconductor material, and the first and second doped regions SR and DR may be omitted. The nano sheet HL may also be referred to as an “active layer” or a “thin body”.

The first doped region SR and the second doped region DR may be doped with the same conductivity type of impurities. The first doped region SR and the second doped region DR may be doped with an N-type conductive impurity or a P-type conductive impurity. The first doped region SR and the second doped region DR may include at least one impurity selected from among arsenic (As), phosphorus (P), boron (B), indium (In), and combinations thereof. The first doped region SR may be electrically coupled to the first conductive line BL, and the second doped region DR may be electrically coupled to the data storage element CAP. The first and second doped regions SR and DR may be referred to as “first and second source/drain regions”.

The nano sheet HL may be horizontally oriented in the second direction D2 from the first conductive line BL.

The second conductive line WL may have a gate all around structure (GAA). For example, the second conductive line WL may surround the nano sheet HL and extend in the third direction D3. A nano sheet dielectric layer GD may be formed between the nano sheet HL and the second conductive line WL. The nano sheet dielectric layer GD may surround a portion of the nano sheet HL, for example, the channel CH of the nano sheet HL. The second conductive line WL may surround the nano sheet HL and may be directly on the nano sheet dielectric layer GD. The second conductive line WL may include a combination of a surrounding body WLS and a surrounding merged portion WLB. The surrounding body WLS may surround the nano sheet HL on the nano sheet dielectric layer GD. The surrounding merged portion WLB may be disposed at both ends of the surrounding body WLS. The surrounding body WLS and the surrounding merged portion WLB may have an integral structure and be formed of the same material. In an embodiment, the surrounding body WLS and the surrounding merged portion WLB may be referred to as an around body and an around merged portion, respectively. The switching element TR may include a GAA transistor.

The second conductive line WL may include a metal-based material, a semiconductive material, or a combination thereof. For example, the second conductive line WL may include molybdenum, molybdenum nitride, ruthenium, titanium nitride, tungsten, polysilicon, or a combination thereof. In an embodiment, the second conductive line WL may include a TiN/W stack in which titanium nitride and tungsten are sequentially stacked. The second conductive line WL may include an N-type work function material or a P-type work function material. The N-type work function material may have a low work function of approximately 4.5 eV or lower, and the P-type work function material may have a high work function of approximately 4.5 eV or higher. The second conductive line WL may include a stack of the low work function material and the high work function material.

The nano sheet dielectric layer GD may be disposed between the nano sheet HL and the second conductive line WL. The nano sheet dielectric layer GD may be referred to as a “gate dielectric layer” or a “channel-side dielectric layer”. The nano sheet dielectric layer GD may include silicon oxide, silicon nitride, metal oxide, metal oxide nitride, metal silicate, a high-k material, a ferroelectric material, an anti-ferroelectric material, or a combination thereof. The nano sheet dielectric layer GD may include SiO₂, Si₃N₄, HfO₂, Al₂O₃, ZrO₂, AlON, HfON, HfSiO, HfSiON, HfZrO, or a combination thereof. The nano sheet dielectric layer GD may be formed by combining deposition of a nano sheet dielectric material and thermal oxidation of the nano sheet HL. The nano sheet dielectric layer GD may be deposited on the nano sheet HL. The nano sheet dielectric layer GD may be formed by the thermal oxidation of the nano sheet HL.

The data storage element CAP may include a memory element such as a capacitor. The data storage element CAP may be horizontally disposed in the second direction D2 next to the switching element TR. The data storage element CAP may include a first electrode SN, a second electrode PN, and a dielectric layer DE between the first electrode SN and the second electrode PN. The first electrode SN may horizontally extend in the second direction D2 from the nano sheet HL. The first electrode SN, the dielectric layer DE and the second electrode PN may be horizontally disposed in the second direction D2 and form a two pronged a “C-shape” structure from a side cross-sectional view perspective. The first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces. The vertical outer surface of the first electrode SN may vertically extend in the first direction D1, and the horizontal outer surfaces of the first electrode SN may horizontally extend in the second direction D2 or the third direction D3. The inner space of the first electrode SN may form a three-dimensional space. The dielectric layer DE may conformally cover the inner and outer surfaces of the first electrode SN. The second electrode PN may be disposed in the inner space of the first electrode SN on the dielectric layer DE. Some of the outer surfaces of the first electrode SN may be electrically coupled to the second contact node SNC and the second doped region DR of the nano sheet HL via the second contact node SNC. The second electrode PN of the data storage element CAP may be coupled to a common plate PL. The first electrode SN may be referred to as a “storage node”.

The data storage element CAP may have a three-dimensional structure. The first electrode SN may have a three-dimensional structure, and the first electrode SN having the three-dimensional structure may have the three-dimensional structure that is horizontally oriented in the second direction D2. As an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically coupled to the second doped region DR of the nano sheet HL. The dielectric layer DE and the second electrode PN may be disposed on the cylindrical inner surfaces and cylindrical outer surfaces of the first electrode SN. In an embodiment, the first electrode SN may have a semi-cylindrical shape. Specifically, the semi-cylindrical shape may refer to a structure in which the second electrode PN partially covers the outer surfaces of the first electrode SN.

In an embodiment, the first electrode SN may have a pillar shape or a pylinder shape. The pylinder shape may refer to a structure in which a pillar shape and a cylindrical shape are merged.

The first electrode SN and the second electrode PN may include metal, noble metal, metal nitride, conductive metal oxide, conductive noble metal oxide, metal carbide, metal silicide, or a combination thereof. For example, the first electrode SN and the second electrode PN may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium silicon nitride/titanium nitride/tungsten (TiSiN/TiN/W) stack, or a combination thereof. The second electrode PN may also include a combination of a metal-based material and a silicon-based material. For example, the second electrode PN may be a titanium nitride/silicon germanium/tungsten nitride (TiN/SiGe/WN) stack. In the titanium nitride/silicon germanium/tungsten nitride (TiN/SiGe/WN) stack, silicon germanium may be a gap-fill material that fills the inside of the first electrode SN, and titanium nitride (TiN) may serve as the second electrode PN of the data storage element CAP, and tungsten nitride may be a low-resistance material. In an embodiment, the second electrode PN may include a titanium nitride/tungsten/polysilicon (TiN/W/Poly-Si) stack.

The dielectric layer DE may be referred to as a “capacitor dielectric layer” or a “memory layer”. The dielectric layer DE may include silicon oxide, silicon nitride, a high-k material, a perovskite material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). In an embodiment, the dielectric layer DE may be formed of a composite layer including two or more layers of the above-described high-k material.

The dielectric layer DE may be formed of zirconium (Zr)-based oxide. The dielectric layer DE may have a stack structure containing zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃) and zirconium oxide (ZrO₂) are sequentially stacked. Each of the ZA stack and the ZAZ stack may be referred to as a “zirconium oxide (ZrO2)-based layer. In an embodiment, the dielectric layer DE may be formed of hafnium (Hf)-based oxide. The dielectric layer DE may have a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃) and hafnium oxide (HfO₂) are sequentially stacked. Each of the HA stack and the HAH stack may be referred to as a “hafnium oxide (HfO₂)-based layer”. In the ZA stack, ZAZ stack, HA stack and HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material having a greater band gap energy than the high-k material. The dielectric layer DE may include silicon oxide (SiO₂) as a high band gap material other than aluminum oxide (Al₂O₃). Since the dielectric layer DE includes a high band gap material, leakage current may be suppressed. The high band gap material may be thinner than the high-k material. In an embodiment, the dielectric layer DE may include a stack structure in which a high-k material and a high band gap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH(HfO₂/ZrO₂/Al₂O₃/ZrO₂/HfO₂) stack, a ZHZAZHZ(ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA(Al₂O₃/HfO₂/ZrO₂/Al₂O₃/ZrO₂/HfO₂/Al₂O₃) stack. In the above-described stack structures, aluminum oxide (Al₂O₃) may be thinner than zirconium oxide (ZrO₂) and hafnium oxide (HfO₂).

In an embodiment, the dielectric layer DE may include a high-k material and a high band gap material, and the dielectric layer DE may have a laminated structure in which a plurality of high-k materials and a plurality of high band gap materials are stacked, or an intermixed structure in which a high-k material and a high band gap material are intermixed.

In an embodiment, the dielectric layer DE may include a ferroelectric material, an anti-ferroelectric material, or a combination thereof. For example, the dielectric layer DE may include HfZrO.

In an embodiment, the dielectric layer DE may include a combination of a high-k material and a ferroelectric material, a combination of a high-k material and an anti-ferroelectric material, or a combination of a high-k material or a ferroelectric material and an anti-ferroelectric material.

In an embodiment, an interface control layer may be further formed between the first electrode SN and the dielectric layer DE to alleviate leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced by another data storage material. For example, the data storage material may be a thyristor, a phase-change material, a Magnetic Tunnel Junction (MTJ), or a variable resistance material.

The memory cell MC may further include a first contact node BLC and a second contact node SNC. The first contact node BLC may be disposed between the first conductive line BL and the nano sheet HL. The first contact node BLC may include a metal-based material or a semiconductive material. For example, the first contact node BLC may include titanium, titanium nitride, tungsten, or a combination thereof. In addition, the first contact node BLC may include doped polysilicon, and the first doped region SR may include an impurity diffused from the first contact node BLC. The second contact node SNC may be disposed between the nano sheet HL and the first electrode SN. The second contact node SNC may include a metal-based material or a semiconductive material. For example, the second contact node SNC may include titanium, titanium nitride, tungsten, or a combination thereof. In addition, the second contact node SNC may include doped silicon, and the second doped region DR may include an impurity diffused from the second contact node SNC. The height (also referred to as a length) of the first contact node BLC in the first direction D1 may be less than that of the second contact node SNC in the first direction D1. The height of the first contact node BLC in the first direction D1 may be greater than that of the channel CH in the first direction D1.

In an embodiment, the second contact node SNC may be selectively grown from the wide sheet WS of the nano sheet HL. The second contact node SNC may be formed by selective epitaxial growth (SEG). For example, the second contact node SNC may be a silicon epitaxial layer formed by the selective epitaxial growth (SEG). The second contact node SNC may be a doped silicon epitaxial layer.

In an embodiment, the first contact node BLC may be selectively grown from the narrow sheet NS of the nano sheet HL. The first contact node BLC may be formed by selective epitaxial growth (SEG). For example, the first contact node BLC may be a silicon epitaxial layer formed by the selective epitaxial growth (SEG). The first contact node BLC may be a doped silicon epitaxial layer.

The first contact node BLC may be a narrow sheet-side contact node, and the second contact node SNC may be a wide sheet-side contact node.

The nano sheet HL may include a first edge and a second edge. The first edge of the nano sheet HL refers to a portion of the first doped region SR which is electrically coupled to the first conductive line BL. The second edge of the nano sheet HL refers to a portion of the second doped region DR electrically coupled to the first electrode SN of the data storage element CAP.

The memory cell MC may further include an ohmic contact layer BLO disposed between the first contact node BLC and the first conductive line BL. The ohmic contact layer BLO may include a metal silicide. In an embodiment, the memory cell MC may further include an ohmic contact layer formed between the second contact node SNC and the first electrode SN of the data storage element CAP. The first conductive line BL, the ohmic contact layer BLO, the first contact node BLC and the first doped region SR may be electrically interconnected to one another. The second doped region DR, the second contact node SNC and the first electrode SN of the data storage element CAP may be electrically interconnected to one another.

The memory cell MC may further include a first spacer SP1 and a second spacer SP2. The first spacer SP1 may be disposed between the second conductive line WL and the second doped region DR. The second spacer SP2 may be disposed between the first conductive line BL and the second conductive line WL. The first and second spacers SP1 and SP2 may extend in the third direction D3 while surrounding the nano sheet HL. That is, the first and second spacers SP1 and SP2 may surround opposite edge portions of the nano sheet HL while being disposed on both sidewalls of the second conductive line WL.

The first and second spacers SP1 and SP2 may each have a double liner structure (as illustrated) or a single liner structure (not shown). For example, the double liner structure of the first spacer SP1 may include a stack of a first liner S1 and a second liner S2. The double liner structure of the second spacer SP2 may include a stack of a third liner L1 and a fourth liner L2. The first and second spacers SP1 and SP2 may each include a dielectric material. The first and second spacers SP1 and SP2 may each include silicon oxide, silicon nitride, or a combination thereof. The first liner S1 of the first spacer SP1 and the fourth liner L2 of the second spacer SP2 may each include silicon oxide. The second liner S2 of the first spacer SP1 and the third liner L1 of the second spacer SP2 may each include silicon nitride. The fourth liner L2 may partially fill an inner space of the third liner L1. The first liner S1 of the first spacer SP1 and the nano sheet dielectric layer GD may include the same material.

The first conductive line BL may include a plurality of horizontal extension portions BLE1, BLE2, and BLE3. The horizontal extension portions BLE1, BLE2, and BLE3 may extend in the second direction D2. The horizontal extension portions BLE1, BLE2, and BLE3 may include an inner horizontal extension portion BLE2 and outer horizontal extension portions BLE1 and BLE3. The inner horizontal extension portion BLE2 of the first conductive line BL may be disposed in a gap defined between the third liners L1 of the second spacer SP2 which are vertically adjacent to each other. Accordingly, the inner horizontal extension portion BLE2 of the first conductive line BL may be electrically coupled to the ohmic contact layer BLO.

The outer horizontal portions BLE1 and BLE3 of the first conductive line BL may extend to be disposed inside one side of the second spacer SP2 that is not filled with the fourth liner L2. Accordingly, the outer horizontal portions BLE1 and BLE3 of the first conductive line BL may contact the fourth liner L2 of the second spacer SP2. In an embodiment, the outer horizontal portions BLE1 and BLE3 of the first conductive line BL may be omitted.

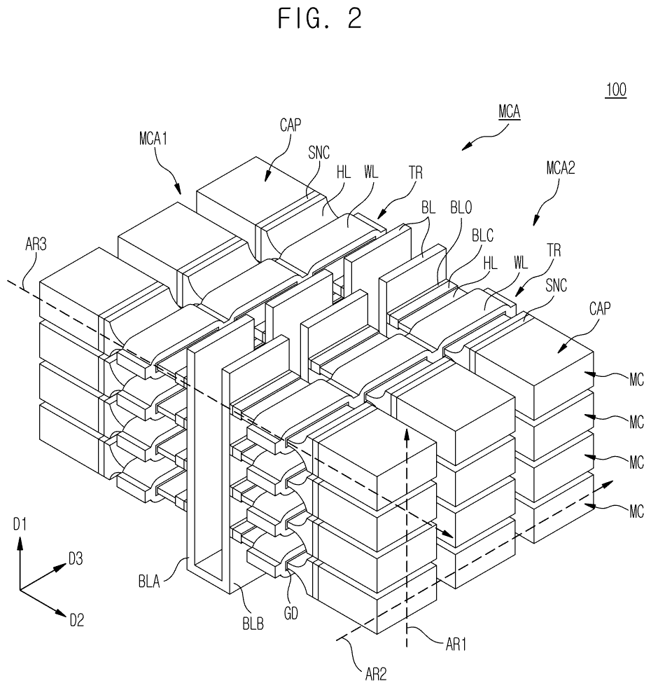

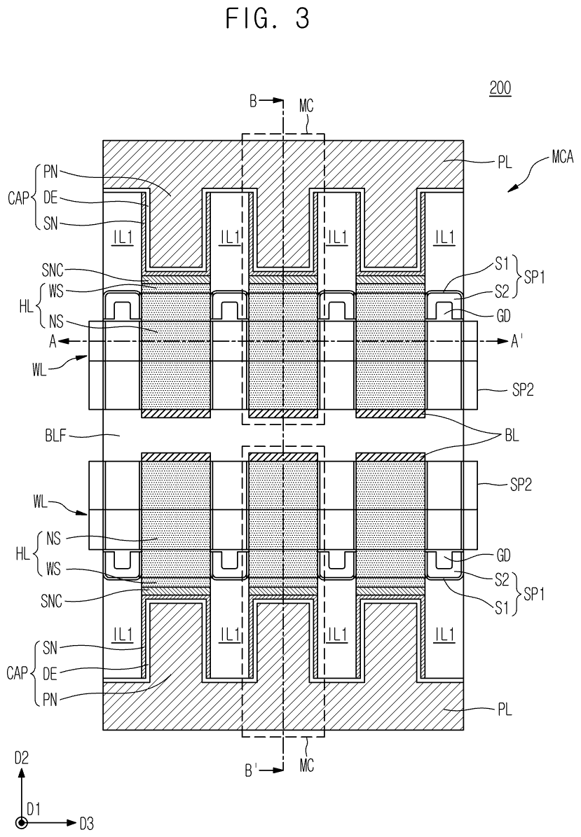

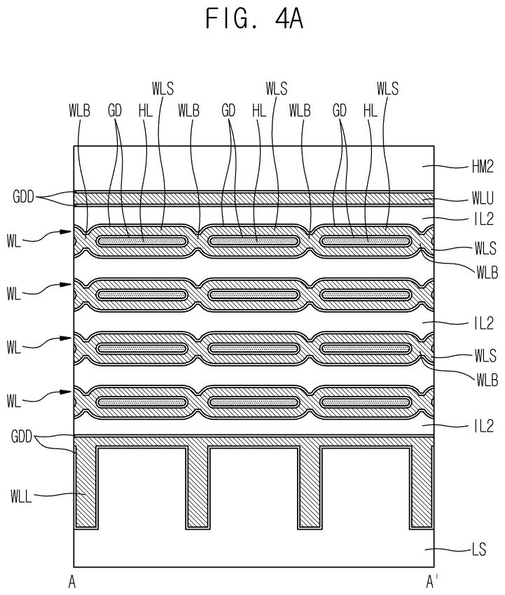

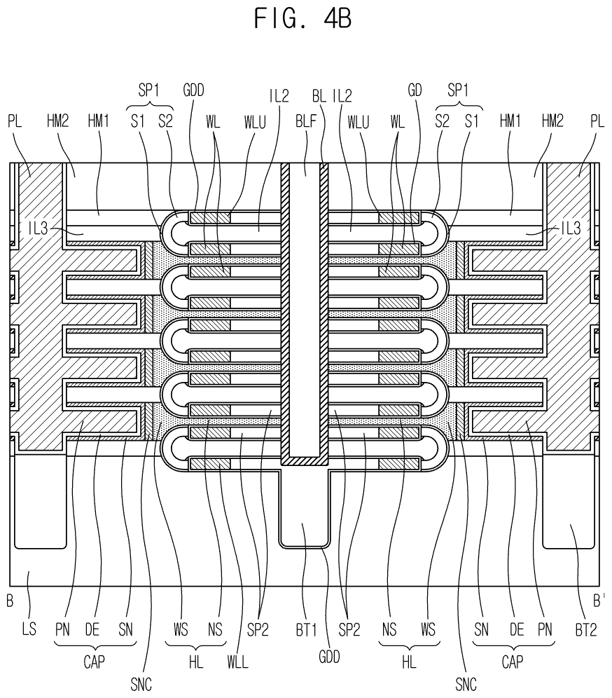

FIG. 2 is a schematic perspective view illustrating a semiconductor device 100 in accordance with an embodiment of the present disclosure. FIG. 3 is a schematic plan view illustrating a semiconductor device 200 in accordance with an embodiment of the present disclosure. FIG. 4A is a cross-sectional view illustrating the semiconductor device 200 taken along line A-A′ of FIG. 3. FIG. 4B is a cross-sectional view illustrating the semiconductor device 200 taken along line B-B′ of FIG. 3.

Referring to FIG. 2, the semiconductor device 100 may include a memory cell array MCA. The memory cell array MCA may include a plurality of memory cells MC vertically stacked in a first direction D1. The memory cell array MCA may also include a plurality of memory cells MC horizontally disposed in a second direction D2. The memory cell array MCA may further include a plurality of memory cells MC horizontally disposed in a third direction D3.

Each of the memory cells MC may include a first conductive line BL, a switching element TR, and a data storage element CAP, with the switching element TR disposed between the first conductive line BL and the data storage element CAP. The switching element TR may include a second conductive line WL, a nano sheet dielectric layer GD, and a nano sheet HL, with the nano sheet dielectric layer GD disposed between the nano sheet HL and the second conductive line WL. The memory cell MC may further include a first contact node BLC, an ohmic contact layer BLO, and a second contact node SNC. The memory cell MC may have the same structure and materials as the memory cell MC illustrated in FIGS. 1A and 1B. As described with reference to FIGS. 1A and 1B, the second conductive line WL may include a surrounding body WLS and a surrounding merged portion WLB.

The memory cell array MCA may include a column array AR1 of the memory cells MC and a row array AR2 of the memory cells MC. The column array AR1 may include the plurality of memory cells MC vertically stacked in the first direction D1. The memory cells MC of the column array AR1 may share the first conductive line BL. The row array AR2 may include the plurality of memory cells MC horizontally disposed in the third direction D3. The memory cells MC of the row array AR2 may share the second conductive line WL. The second conductive line WL of the memory cell array MCA may have a structure in which a plurality of surrounding bodies and a plurality of surrounding merged portions are mutually merged. The surrounding merged portions may be disposed in gaps between the nano sheets HL where the nano sheet dielectric layers GD are formed.

The column array AR1 may include a vertical arrangement of the nano sheets HL in the first direction D1. The first conductive line BL may be coupled in common to the nano sheets HL of the vertical arrangement, and the second conductive lines WL each surrounding a different one of the nano sheets HL of the vertical arrangement.

The row array AR2 may include a horizontal arrangement of the nano sheets HL in the third direction D3 and the first conductive lines BL may each be coupled to a different one of the nano sheets HL of the horizontal arrangement, and the second conductive line WL surrounding the nano sheets HL of the horizontal arrangement.

The first direction D1 may be a vertical direction, and the third direction D3 may be a horizontal direction. The memory cell array MCA may further include a horizontal level array AR3, and the horizontal level array AR3 may include the plurality of memory cells MC disposed at the same horizontal level in a second direction D2. Neighboring memory cells MC of the horizontal level array AR3 may share the first conductive line BL.

The memory cell array MCA may include first and second sub-cell arrays MCA1 and MCA2. The first and second sub-cell arrays MCA1 may each include a three-dimensional array of memory cells MC. The first sub-cell array MCA1 and the second sub-cell array MCA2 may share the first conductive line BL. The first conductive line BL may include a first vertical conductive line BLA and a second vertical conductive line BLB, and a bottom portion of the first vertical conductive line BLA and a bottom portion of the second vertical conductive line BLB may be merged with each other. Hence, the first conductive line BL may have a U-shape formed by the merging of the first and second vertical conductive lines BLA and BLB. The memory cells MC of the first sub-cell array MCA1 may share the first vertical conductive line BLA. The memory cells MC of the second sub-cell array MCA2 may share the second vertical conductive line BLB. In this way, the neighboring first and second sub-cell arrays MCA1 and MCA2 may have a mirror-type structure of sharing the first conductive line BL. From the perspective of a top view, the first and second vertical conductive lines BLA and BLB may each have a rectangular shape.

A memory cell array MCA of the semiconductor device 200 illustrated in FIGS. 3 to 4B may be similar to the memory cell array MCA illustrated in FIG. 2, and memory cells MC of the memory cell array MCA may be similar to the memory cells MC illustrated in FIGS. 1A and 1B. Hereinafter, detailed descriptions of overlapping components are provided with reference to FIGS. 1A, 1B and 2.

Referring to FIGS. 3, 4A and 4B, the semiconductor device 200 may include the memory cell array MCA over a lower structure LS. The memory cell array MCA may include a three-dimensional array of the memory cells MC. The three-dimensional array of the memory cells MC may include a column array of the memory cells MC and a row array of the memory cells MC. The column array of the memory cells MC may include a plurality of memory cells MC stacked in a first direction 1, and the row array of the memory cells MC may include a plurality of memory cells MC horizontally disposed in a second direction D2. The row array of the memory cells MC may include a plurality of memory cells MC horizontally disposed in a third direction D3. The memory cell array MCA may include sub-memory cell arrays disposed adjacent to each other in the second direction D2. Each of the sub-memory cell arrays may have a mirror-type structure in which two memory cells MC share a common plate PL. In an embodiment, the semiconductor device 200 may further include sub-memory cell arrays each having a mirror-type structure in which two memory cells MC share a first conductive line BL. When the column array of the memory cells MC is repeated in the third direction D3, the row array of the memory cells MC may be configured.

Each of the memory cells MC may include the first conductive line BL, a switching element TR, and a data storage element CAP. The switching element TR may include a second conductive line WL, a nano sheet dielectric layer GD, and a nano sheet HL. The memory cell MC may further include a first contact node BLC, an ohmic contact layer BLO, and a second contact node SNC. The second conductive line WL may include a surrounding body WLS and a surrounding merged portion WLB. The height of the surrounding body WLS in the first direction D1 may be greater than that of the surrounding merged portion WLB. The nano sheet dielectric layer GD may include a first portion formed on all surfaces of the nano sheet HL and a second portion formed on an outer surface of the second conductive line WL. The first portion of the nano sheet dielectric layer GD may be disposed between the nano sheet HL and the second conductive line WL. The second portion of the nano sheet dielectric layer GD may be disposed between the second conductive line WL and a second inter-cell dielectric layer IL2.

Each of the second conductive lines WL of the memory cell array MCA may have a structure in which a plurality of surrounding bodies WLS and a plurality of surrounding merged portions WLB are mutually merged. Each of the surrounding merged portions WLB may be disposed in a gap between the nano sheets HL where the nano sheet dielectric layers GD are formed. The surrounding bodies WLS and the surrounding merged portions WLB may each have an integral structure of the same material. Upper and lower surfaces of the second conductive line WL may include a plurality of shallow concavities defined by the surrounding merged portions WLB. That is, the upper and lower surfaces of the second conductive line WL may not have a flat shape but may have a non-flat shape due to the plurality of shallow concavities.

First inter-cell dielectric layers IL1 may be formed between the memory cells MC disposed in the third direction D3. The first inter-cell dielectric layers IL1 may be disposed between the data storage elements CAP in the third direction D3.

The second inter-cell dielectric layers IL2 may be formed between the memory cells MC stacked in the first direction D1. The second inter-cell dielectric layers IL2 may be disposed between the second conductive lines WL in the first direction D1. The second inter-cell dielectric layers IL2 may each include a plurality of convex-shaped regions (referred to simply as convexities). The convexities of the second inter-cell dielectric layers IL2 may be portions that fill shallow concave-shaped regions (referred to simply as concavities of the second conductive lines WL. Upper and lower surfaces of the second inter-cell dielectric layers IL2 may not have a flat shape but may have a non-flat shape due to the plurality of convexities. Among the second inter-cell dielectric layers IL2, an uppermost second inter-cell dielectric layer IL2 and a lowermost second inter-cell dielectric layers IL2 may each include a combination of a flat shape and a non-flat shape.

Third inter-cell dielectric layers IL3 may be formed between the data storage elements CAP stacked in the first direction D1. The third inter-cell dielectric layers IL3 may each include silicon oxide. Each of the third inter-cell dielectric layers IL3 may be disposed between first electrodes SN of the data storage elements CAP in the first direction D1.

The first to third inter-cell dielectric layers IL1, IL2 and IL3 may each include silicon oxide, silicon carbon oxide, an air gap, air gap-embedded oxide, or a combination thereof.

The memory cell array MCA may include a plurality of second conductive lines WL vertically stacked in the first direction D1. The memory cell array MCA may include a plurality of nano sheets HL vertically stacked in the first direction D1. The memory cell array MCA may include a plurality of data storage elements CAP vertically stacked in the first direction D1. The memory cell array MCA may include a plurality of first conductive lines BL spaced apart in the third direction D3. The memory cell array MCA may further include dummy second conductive lines WLU and WLL. The dummy second conductive lines WLU and WLL may not surround the nano sheet HL. The dummy second conductive lines WLU and WLL may each have a non-surrounding shape.

A first bottom protective layer BT1 may be formed below the first conductive line BL, and a second bottom protective layer BT2 may be formed below the common plate PL. The first and second bottom protective layers BT1 and BT2 may include silicon oxide, silicon nitride, silicon carbon oxide, or a combination thereof.

Dummy structures GDD may be disposed on the peripheries of the first and second bottom protective layers BT1 and BT2. The dummy structures may include dummy nano sheet dielectric layers GDD. The dummy nano sheet dielectric layers GDD may contact the dummy second conductive lines WLU and WLL.

A plurality of hard mask layers HM1 and HM2 may be disposed over an uppermost second conductive line WL.

A first spacer SP1 may be disposed between the second conductive line WL and the first electrode SN of the data storage element CAP. A second spacer SP2 may be disposed between the second conductive line WL and the first conductive line BL. The second spacer SP2 may be disposed on an upper surface and a lower surface of the second inter-cell dielectric layer IL2. The second spacer SP1 may be formed on a first side of the second conductive lines WL, and the second spacer SP2 may be formed on a second side of the second conductive lines WL. The first spacer SP1 may cover one side of the second inter-cell dielectric layer IL2. One side of the second inter-cell dielectric layer IL2 may have a sphere-like shape, and the first spacer SP1 may have a cup shape, for example, a “⊃” shape. The first spacer SP1 may cover the sphere-like shape of the second inter-cell dielectric layer IL2.

The first spacer SP1 may be disposed between the second conductive line WL and the second doped region DR. The second spacer SP2 may be disposed between the first conductive line BL and the second conductive line WL. The first spacer SP1 and the second spacer SP2 may extend in the third direction D3 while surrounding the nano sheet HL. That is, the first and second spacers SP1 and SP2 may be disposed on both sides of the second conductive line WL and surround the nano sheet HL.

The first spacer SP1 and the second spacer SP2 may each have a double liner structure or a single liner structure. For example, the first spacer SP1 may have a double liner structure formed with a stack of a first liner S1 and a second liner S2, while the second spacer SP2 may have a single liner structure. In an embodiment, as illustrated, for example, in FIG. 1B, the second spacer SP2 may have a double liner structure. The first and second spacers SP1 and SP2 may each include a dielectric material. The first and second spacers SP1 and SP2 may each include silicon oxide, silicon nitride, silicon carbon oxide, an air gap, or a combination thereof. The first liner S1 of the first spacer SP1 may include silicon oxide. The first liner S1 of the first spacer SP1 and the nano sheet dielectric layer GD may include the same material. The first liner S1 of the first spacer SP1 and the nano sheet dielectric layer GD may be discontinuous.

The nano sheets HL of the switching elements TR which are horizontally disposed in the third direction D3 may share one second conductive line WL. The nano sheets HL of the switching elements TR which are horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line WL.

The third inter-cell dielectric layers IL3 may be disposed between the first electrodes SN of the data storage elements CAP in the third direction D3. The first electrodes SN stacked in the first direction D1 may be isolated from each other by the third inter-cell dielectric layers IL3. The second electrodes PN of the data storage elements CAP may be coupled to the common plate PL.

The lower structure LS may be disposed at a lower level than the memory cell array MCA. The lower structure LS may be formed of a material suitable for semiconductor processing. The lower structure LS may include at least one of a conductive material, a dielectric material and a semiconductive material. Various materials may be formed over the lower structure LS.

In an embodiment, the lower structure LS may include a semiconductor substrate. The lower structure LS may be formed of a silicon-containing material. The lower structure LS may include silicon, monocrystalline silicon, polysilicon, amorphous silicon, silicon germanium, monocrystalline silicon germanium, polycrystalline silicon germanium, carbon-doped silicon, a combination thereof, or multi-layers thereof. The lower structure LS may include another semiconductive material, such as germanium. The lower structure LS may include a III/V-group semiconductor substrate, for example, a chemical compound semiconductor substrate such as gallium arsenide (GaAs). The lower structure LS may include a Silicon-On-Insulator (SOI) substrate. The lower structure LS may be referred to as a “base body”.

In an embodiment, the lower structure LS may include a metal wiring structure, a dielectric structure, a conductive structure, a bonding pad structure, another memory, or a peripheral circuit portion. For example, the lower structure LS may include a structure in which the peripheral circuit portion, the metal wiring structure and the bonding pad structure are sequentially stacked. The memory cell array MCA and the peripheral circuit portion of the lower structure LS may be bonded by wafer bonding. The wafer bonding may include pad bonding, hybrid bonding, oxide-to-oxide bonding, metal-to-metal bonding, or a combination thereof. The peripheral circuit portion of the lower structure LS may be disposed at a lower level than the memory cell array MCA. This may be referred to as a “PERI under cell (PUC) structure”or a “cell array over PERI (COP) structure”.

The peripheral circuit portion may include at least one control circuit for driving the memory cell array MCA. At least one control circuit of the peripheral circuit portion may include an N-channel transistor, a P-channel transistor, a CMOS circuit, or a combination thereof. At least one control circuit of the peripheral circuit portion may include an address decoder circuit, a read circuit, or a write circuit. At least one control circuit of the peripheral circuit portion may include a planar channel transistor, a recess channel transistor, a buried gate transistor, or a fin channel transistor (FinFET).

For example, the peripheral circuit portion may include sub-word line drivers and a sense amplifier. The second conductive lines WL may be coupled to the sub-word line drivers. The first conductive line BL may be coupled to the sense amplifier.

In an embodiment, the lower structure LS may include a semiconductor substrate, the memory cell array MCA disposed over the lower structure LS, and the peripheral circuit portion disposed over the memory cell array MCA. This structure may be referred to as a “PERI over cell (POC) structure”or a “cell under PERI (CUP) structure”.

In an embodiment, the memory cell array MCA may include DRAM, embedded DRAM, NAND, FeRAM, STTRAM, PCRAM, or ReRAM.

Referring back to FIG. 3, a supporter BLF may be formed between the first conductive lines BL. The supporter BLF may vertically extend in the first direction D1 and horizontally extend in the third direction D3. The first conductive lines BL disposed adjacent to each other in the second direction D2 may be isolated by the supporter BLF. The first conductive lines BL disposed adjacent to each other in the third direction D3 may be isolated by the supporter BLF and the second spacer SP2. The supporter BLF may include a dielectric material. The supporter BLF may include silicon oxide, silicon nitride, an air gap, or a combination thereof. The supporter BLF may be referred to as a “vertical dielectric layer”.

As described with reference to FIGS. 3 to 4B, the semiconductor device 200 may include an array of the memory cells MC vertically stacked, and the array may include the switching elements TR horizontally oriented, the first conductive lines BL vertically oriented, and the data storage elements CAP horizontally oriented. The switching elements TR horizontally oriented may include the nano sheets HL and the second conductive lines WL horizontally oriented, and the nano sheets HL may include first doped regions SR, second doped regions DR, and channels CH between the first and second doped regions SR and DR. The second conductive lines WL horizontally oriented may have a gate all around (GAA) structure, and the gate all around (GAA) structure of the second conductive lines WL horizontally oriented may surround all surfaces of the channels CH of the nano sheets HL. The second conductive lines WL horizontally oriented may surround the channels CH of the nano sheets HL at the same horizontal level. The data storage elements CAP horizontally oriented may include the first electrodes SN horizontally oriented. The first electrodes SN may be electrically coupled to the second doped regions DR. The data storage elements CAP may further include the second electrodes PN and dielectric layers DE between the first electrodes SN and the second electrodes PN. The first conductive lines BL vertically oriented may be electrically coupled to the first doped regions SR. The second conductive lines WL horizontally oriented may include the surrounding bodies WLS surrounding the channels CH and the surrounding merged portions WLB between the surrounding bodies WLS. The surrounding merged portions WLB may each include a seam-free conductive material. The surrounding bodies WLS and the surrounding merged portions WLB may each include a conductive material. The second conductive lines WL horizontally oriented may be spaced apart from the channels CH by the nano sheet dielectric layers GD. The nano sheets HL may be horizontally formed in the vertical stack.

From another perspective, referring to FIG. 4A, the semiconductor device 200 may include a vertical stack in which the second inter-cell dielectric layers IL2 are alternately stacked with the nano sheets HL, the first conductive lines BL coupled to first edges of the nano sheets HL and vertically oriented in a stacking direction, i.e., the first direction D1, of the vertical stack, the second conductive lines WL including inner surfaces that face the nano sheets HL and outer surfaces that face the second inter-cell dielectric layers IL2 and horizontally oriented in a direction, i.e., the third direction D3, crossing the stacking direction of the vertical stack, the nano sheet dielectric layers GD formed between the inner surfaces of the second conductive lines WL and the nano sheets HL and formed between the outer surfaces of the second conductive lines WL and the second inter-cell dielectric layers IL2, and the data storage elements CAP each coupled to a different one of second edges of the nano sheets HL. The nano sheets HL may include first doped regions SR, second doped regions DR, and channels CH between the first and second doped regions SR and DR. The second conductive lines WL may have a gate all around (GAA) structure surrounding all surfaces of the channels CH. The second conductive lines WL may surround the channels CH of at the same horizontal level. The second conductive lines WL may include the surrounding bodies WLS surrounding the channels CH and the surrounding merged portions WLB between the surrounding bodies WLS. The surrounding merged portions WLB may each include a seam-free conductive material. The surrounding bodies WLS and the surrounding merged portions WLB may each have an integral structure made of the same conductive material.

From another perspective, the semiconductor device 200 may include a horizontal arrangement of the nano sheets HL and the second conductive line WL surrounding the horizontal arrangement of the nano sheets HL. The second conductive line WL may include the surrounding bodies WLS surrounding the nano sheets HL and the surrounding merged portions WLB each filling a horizontal gap between the nano sheets HL.

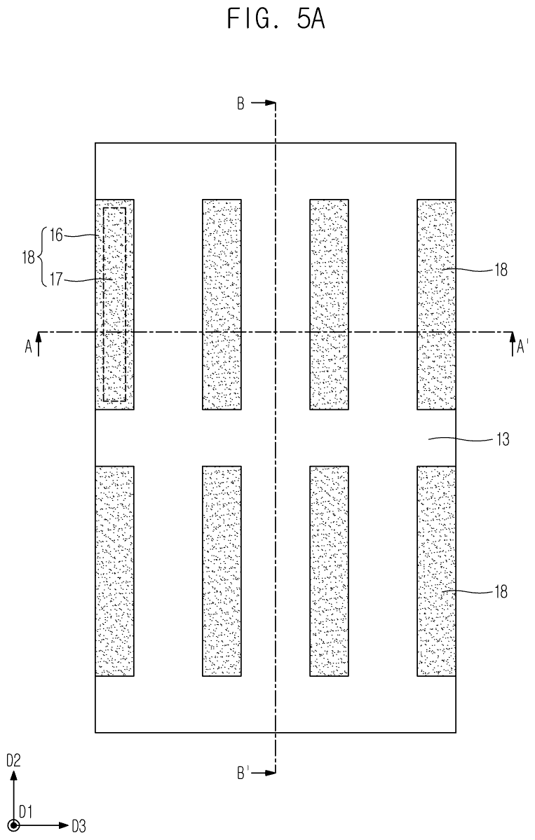

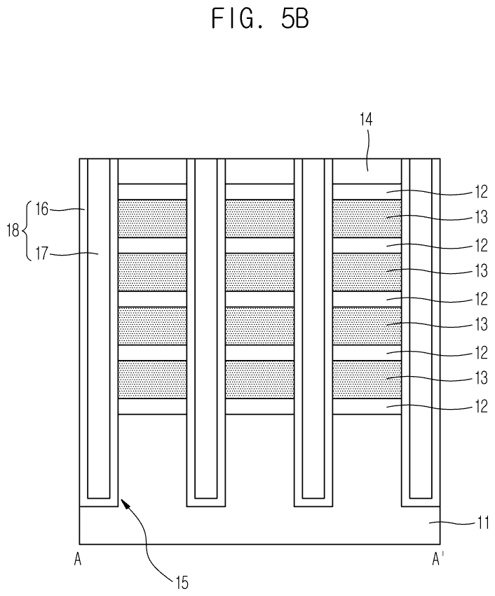

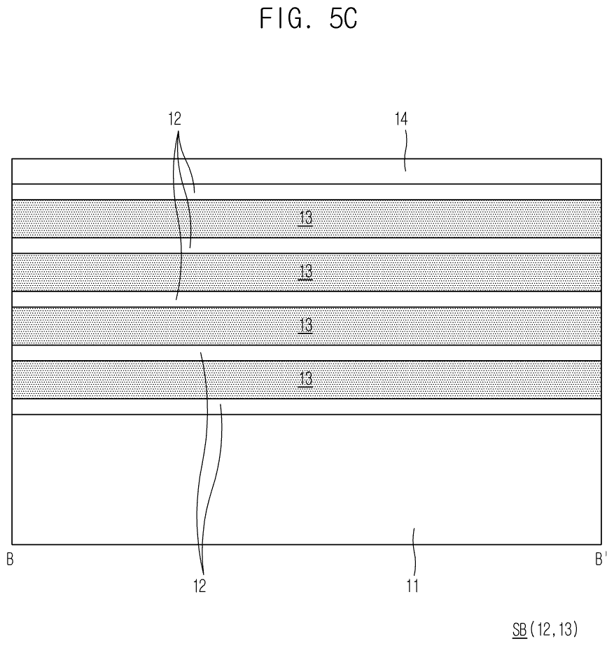

FIGS. 5A to 22B illustrate various views of a semiconductor device formed utilizing a method for fabricating the semiconductor device in accordance with an embodiment of the present disclosure.

FIG. 5A is a plan view illustrating a structure at a second mold layer level for describing a method for forming sacrificial isolation layers 18. FIG. 5B is a cross-sectional view illustrating the structure taken along line A-A′ of FIG. 5A. FIG. 5C is a cross-sectional view illustrating the structure taken along line B-B′ of FIG. 5A.

As illustrated in FIGS. 5A to 5C, a mold stack SB may be formed on a substrate 11.

The substrate 11 may be a material suitable for semiconductor processing. The substrate 11 may include a semiconductive material. The substrate 11 may include a semiconductor substrate. The substrate 11 may be formed of a silicon-containing material. The substrate 11 may include silicon, monocrystalline silicon, polysilicon, amorphous silicon, silicon germanium, monocrystalline silicon germanium, polycrystalline silicon germanium, carbon-doped silicon, a combination thereof, or multi-layers thereof. The substrate 11 may include another semiconductive material, such as germanium. The substrate 11 may include a III/V-group semiconductor substrate, for example, a chemical compound semiconductor substrate such as gallium arsenide (GaAs). The substrate 11 may include a Silicon-On-Insulator (SOI) substrate. The substrate 11 may be referred to as a “base body”.

The mold stack SB may include an alternating stack of first mold layers 12 and second mold layers 13. The first mold layers 12 may be alternately stacked with the second mold layers 13, and the first mold layers 12 and the second mold layers 13 may be epitaxially grown multiple times to form the mold stack SB.

The first mold layers 12 and the second mold layers 13 may be different semiconductive materials. For example, in an embodiment, the first mold layers 12 may include silicon germanium or monocrystalline silicon germanium, and the second mold layers 13 may include monocrystalline silicon. The first mold layers 12 and the second mold layers 13 may be formed by an epitaxial growth process. A lowermost first mold layer 12 may serve as a seed layer during the epitaxial growth process. The first mold layers 12 may be thinner than the second mold layers 13. The first mold layers 12 may include first epitaxially grown layers, and the second mold layers 13 may include second epitaxially grown layers.

In an embodiment, a plurality of monocrystalline silicon germanium layers may be alternately stacked with a plurality of monocrystalline silicon layers in the mold stack SB. For example, the first mold layers 12 may be the monocrystalline silicon germanium layers, and the second mold layers 13 may be the monocrystalline silicon layers. A stack of a monocrystalline silicon germanium layer/a monocrystalline silicon layer (a SiGe/Si stack) may be stacked multiple times. The first mold layers 12 may be referred to as “sacrificial layers”, and the second mold layers 13 may be referred to as “nano sheet target layers”or “recess target layers”.

The mold stack SB may be referred to as a “vertical stack”. A plurality of sacrificial layers may be alternately stacked with a plurality of nano sheet target layers to form the mold stack SB. The sacrificial layers may be monocrystalline silicon germanium layers, and the nano sheet target layers may be monocrystalline silicon layers.

A thickness ratio of the first mold layers 12 and the second mold layers 13 in the mold stack SB may be variously modified. For example, the thickness of each of the first mold layers 12 may be approximately 5 to 20 nm, and the thickness of each of the second mold layers 13 may be approximately 50 to 80 nm. A quantity of alternations of the first mold layers 12 and the second mold layers 13 in the mold stack SB may be variously modified. In an embodiment, a triple stack including the first mold layer 12/the second mold layer 13/the first mold layer 12 may be defined at lowermost and/or uppermost portions of the mold stack SB. The second mold layer 13 of the triple stack may have a smaller thickness than the second mold layer 13 of the mold stack SB.

A first hard mask layer 14 may be formed on the mold stack SB. The first hard mask layer 14 may include a dielectric material such as an oxide-based material, a nitride-based material, a carbon-based material, or a combination thereof. For example, the first hard mask layer 14 may include SiO₂, Si₃N₄, amorphous carbon, or a combination thereof.

Subsequently, portions of the mold stack SB may be etched using the first hard mask layer 14 as a barrier so that a plurality of sacrificial isolation openings 15 may be formed. The sacrificial isolation openings 15 may be initial openings for cell isolation. From the perspective of a top view, cross-sections of the sacrificial isolation openings 15 may each have a rectangular shape. In an embodiment, the cross-sections of the sacrificial isolation openings 15 may each have a circular shape or an oval shape. In an embodiment, the sacrificial isolation openings 15 may be referred to as “sacrificial isolation trenches”. The sacrificial isolation openings 15 may vertically extend in a first direction D1 and extend lengthwise in a second direction D2. The sacrificial isolation openings 15 may be disposed at a predetermined interval in a third direction D3.

Subsequently, the sacrificial isolation layers 18 may be formed to fill the sacrificial isolation openings 15. The sacrificial isolation layers 18 may include the same material. The sacrificial isolation layers 18 may be formed of a dielectric material. The sacrificial isolation layers 18 may have an etch selectivity with respect to the mold stack SB. For example, the sacrificial isolation layers 18 may each include silicon oxide, silicon nitride, silicon carbon oxide, silicon carbon nitride, or a combination thereof. Forming the sacrificial isolation layers 18 may include forming sacrificial isolation materials on the first hard mask layer 14 to fill the sacrificial isolation openings 15 and planarizing the sacrificial isolation materials so that a surface of the first hard mask layer 14 is exposed.

The sacrificial isolation layers 18 may vertically extend in the first direction D1 and extend lengthwise in the second direction D2. The sacrificial isolation layers 18 may be disposed at a predetermined interval in the third direction D3. Each of the sacrificial isolation layers 18 may include a stack of a first sacrificial liner layer 16 and a first sacrificial gap-fill layer 17. The first sacrificial liner layer 16 may be silicon nitride, and the first sacrificial gap-fill layer 17 may be silicon oxide. The sacrificial isolation layers 18 may penetrate the mold stack SB in the first direction D1 and extend partially inside the substrate 11.

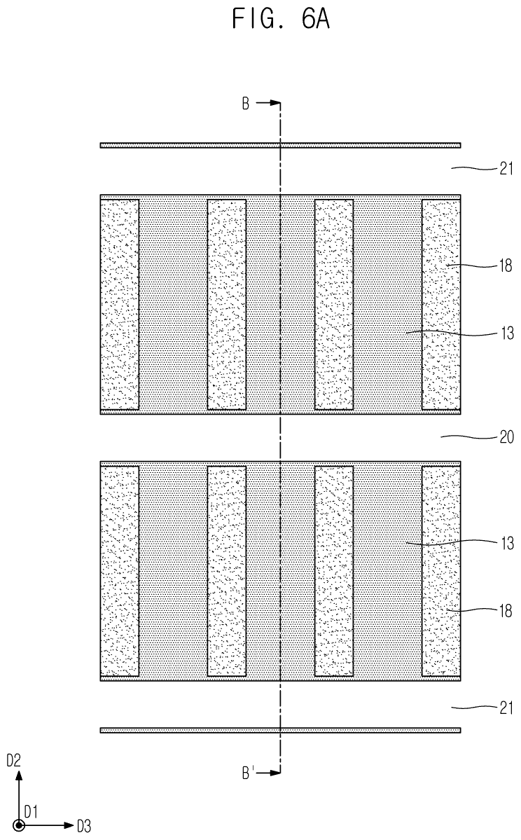

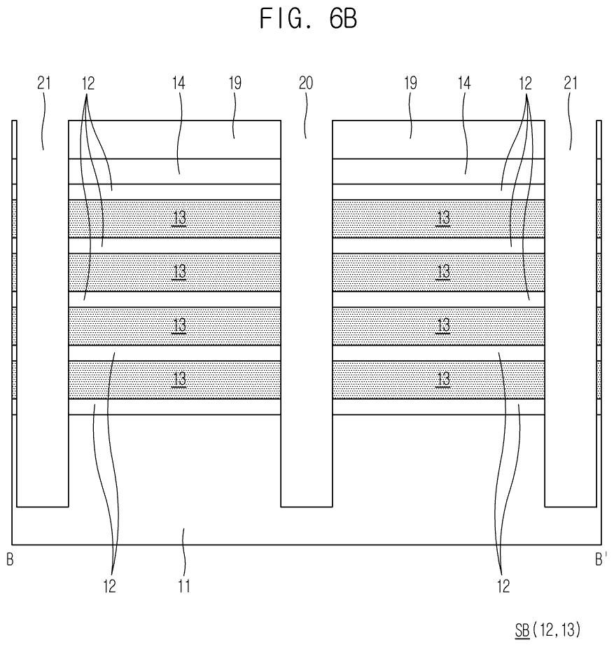

FIG. 6A is a plan view illustrating the structure at the second mold layer level for describing a method for forming sacrificial linear openings 20 and 21. FIG. 6B is a cross-sectional view illustrating the structure taken along line B-B′ of FIG. 6A.

As illustrated in FIGS. 6A and 6B, a second hard mask layer 19 may be formed on the first hard mask layer 14 and the sacrificial isolation layers 18. The second hard mask layer 19 may include silicon nitride. The second hard mask layer 19 may be formed by etching a second hard mask material using a mask layer such as photoresist. The second hard mask layer 19 may have a plurality of line-shaped openings defined therein.

The first hard mask layer 14 may be etched using the second hard mask layer 19 as an etch barrier, and then portions of the mold stack SB may be etched. Accordingly, a plurality of sacrificial linear openings 20 and 21 may be formed between the sacrificial isolation layers 18 in the second direction D2. The sacrificial linear openings 20 and 21 may include a first sacrificial linear opening 20 and a second sacrificial linear opening 21. From the perspective of a top view, the first sacrificial linear opening 20 and the second sacrificial linear opening 21 may be line-shaped openings extending in the third direction D3. The first sacrificial linear opening 20 and the second sacrificial linear opening 21 may vertically extend in the first direction D1. The sacrificial isolation layers 18 may be disposed between the first sacrificial linear opening 20 and the second sacrificial linear opening 21 in the second direction D2. From the perspective of a top view, cross sections of the first and second sacrificial linear openings 20 and 21 may each have a rectangular shape. In an embodiment, the cross sections of the first and second sacrificial linear openings 20 and 21 may each have a circular shape or oval shape. The first and second sacrificial linear openings 20 and 21 may each have a width in the second direction D2 less than a width in the third direction D3. The first and second sacrificial linear openings 20 and 21 may be referred to as “sacrificial linear trenches”. The sacrificial isolation layers 18 may not contact the first and second sacrificial linear openings 20 and 21.

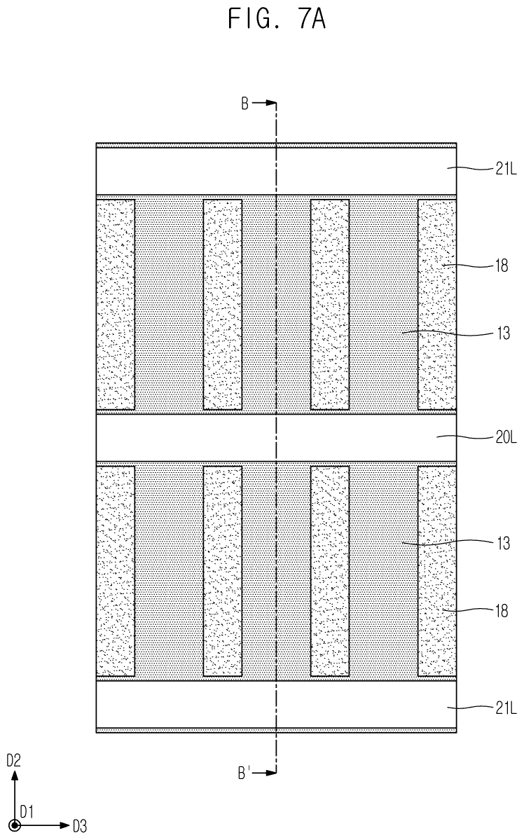

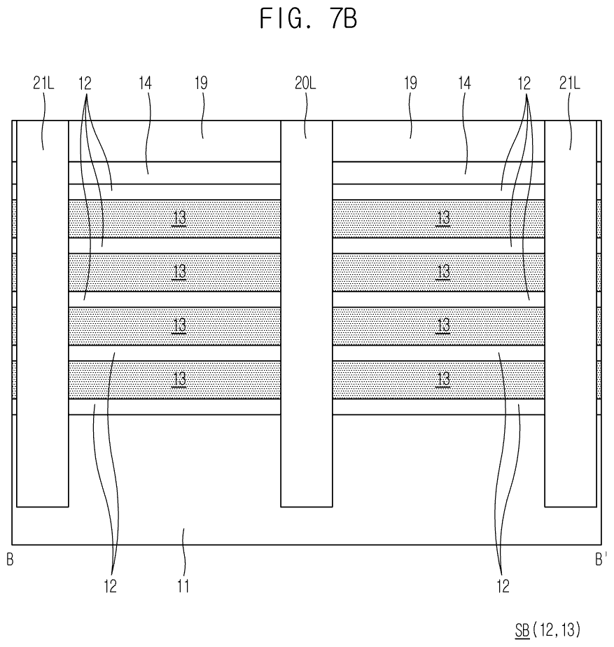

FIG. 7A is a plan view illustrating the structure at the second mold layer level for describing a method for forming linear sacrificial layers 20L and 21L. FIG. 7B is a cross-sectional view illustrating the structure taken along line B-B′ of FIG. 7A.

As illustrated in FIGS. 7A and 7B, the linear sacrificial layers 20L and 21L may be formed to fill the first and second sacrificial linear openings 20 and 21, respectively. The linear sacrificial layers 20L and 21L may include a first linear sacrificial layer 20L and a second linear sacrificial layer 21L. From the perspective of a top view, the first and second linear sacrificial layers 20L and 21L may have line shapes extending in the third direction D3. The first and second linear sacrificial layers 20L and 21L may vertically extend in the first direction D1. The sacrificial isolation layers 18 may be disposed between the first linear sacrificial layer 20L and the second linear sacrificial layer 21L in the second direction D2. From the perspective of a top view, cross sections of the first and second linear sacrificial layers 20L and 21L may each have a rectangular shape. In an embodiment, the cross-sections of the first and second linear sacrificial layers 20L and 21L may each have a circular shape or an oval shape. The first and second linear sacrificial layers 20L and 21L may include the same material. The first and second linear sacrificial layers 20L and 21L may be formed of a dielectric material. For example, the first and second linear sacrificial layers 20L and 21L may each include silicon oxide, silicon nitride, silicon carbon oxide, silicon carbon nitride, or a combination thereof. The sacrificial isolation layers 18 may not contact the first and second linear sacrificial layers 20L and 21L.

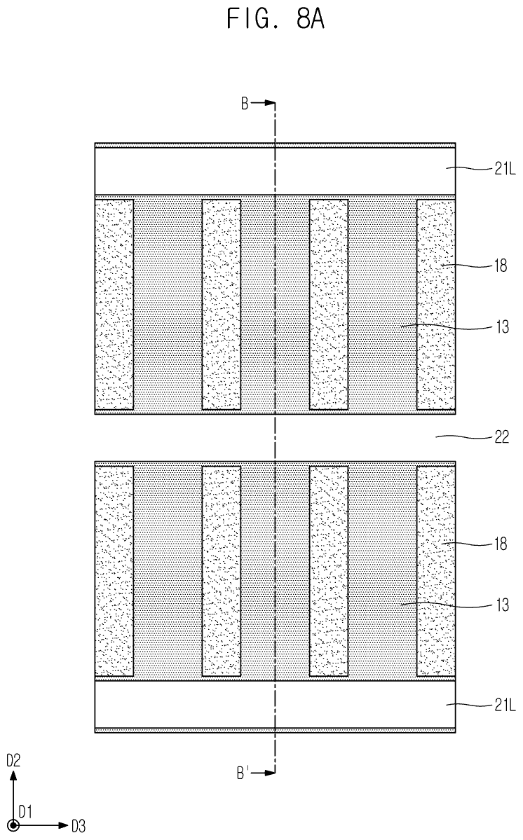

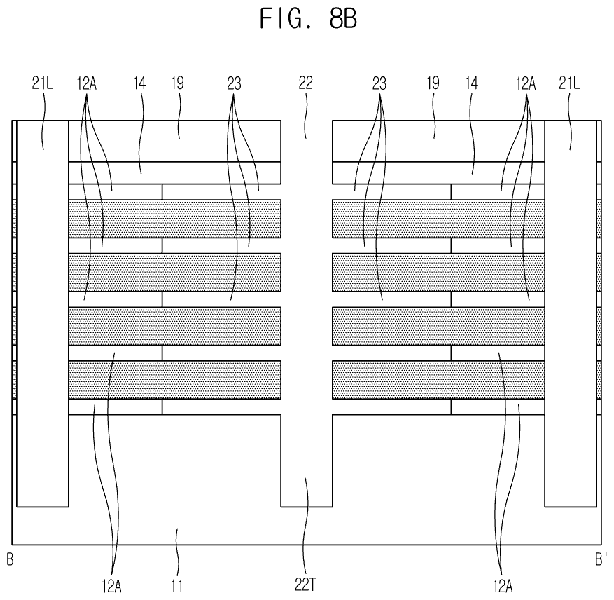

FIG. 8A is a plan view illustrating the structure at the second mold layer level for describing partial recessing of the first mold layers 12. FIG. 8B is a cross-sectional view illustrating the structure taken along line B-B′ of FIG. 8A.

As illustrated in FIGS. 8A and 8B, among the first linear sacrificial layer 20L and the second linear sacrificial layer 21L, the first linear sacrificial layer 20L may be selectively removed. Accordingly, a first linear opening 22 may be formed. A bottom portion 22T of the first linear opening 22 may be disposed in the substrate 11. From the perspective of a top view, the first linear opening 22 may be disposed horizontally spaced apart from the second linear sacrificial layer 21L in the second direction D2.

Subsequently, the first mold layers 12 may be selectively recessed through the first linear opening 22. In order to selectively recess the first mold layers 12, a difference in etch selectivity between the first mold layers 12 and the second mold layers 13 may be used. The first mold layers 12 may be removed using a wet etch process or a dry etch process. For example, when the first mold layers 12 include silicon germanium layers and the second mold layers 13 include monocrystalline silicon layers, the silicon germanium layers may be etched using an etchant or etch gas having a selectivity with respect to the monocrystalline silicon layers. The first mold layers having an original thickness may remain as indicated by reference numeral “12A”. Partial recesses 23 may be formed between the second mold layers 13.

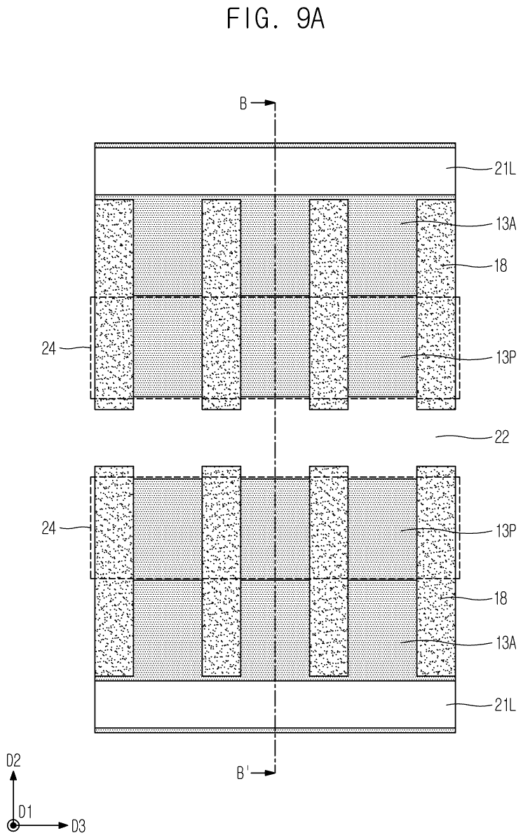

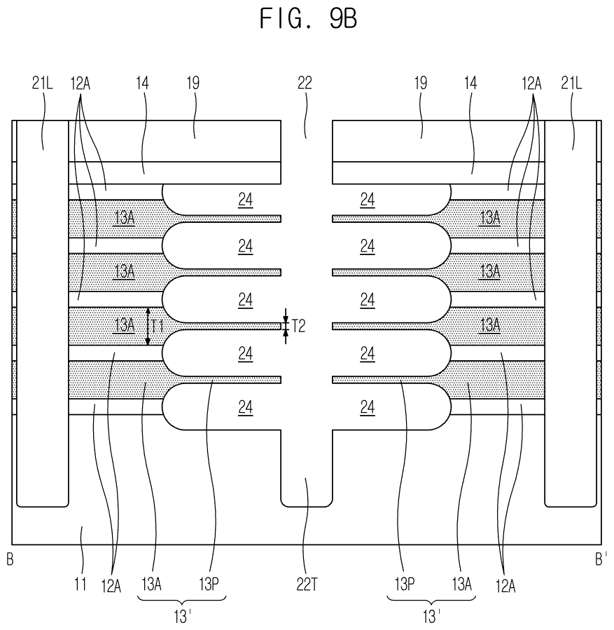

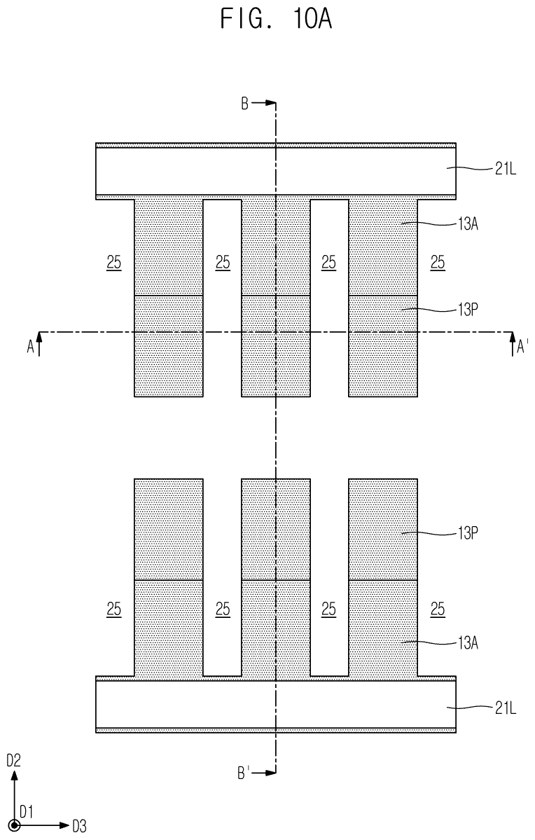

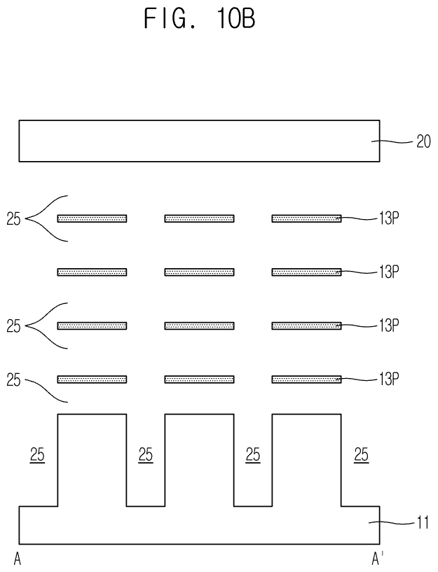

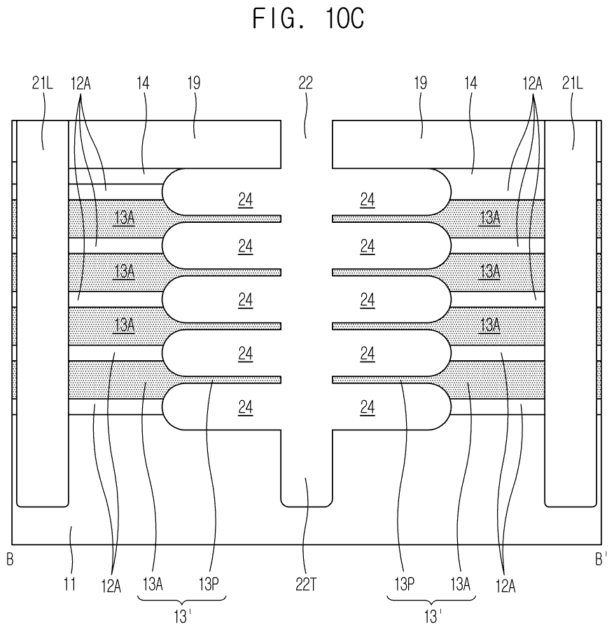

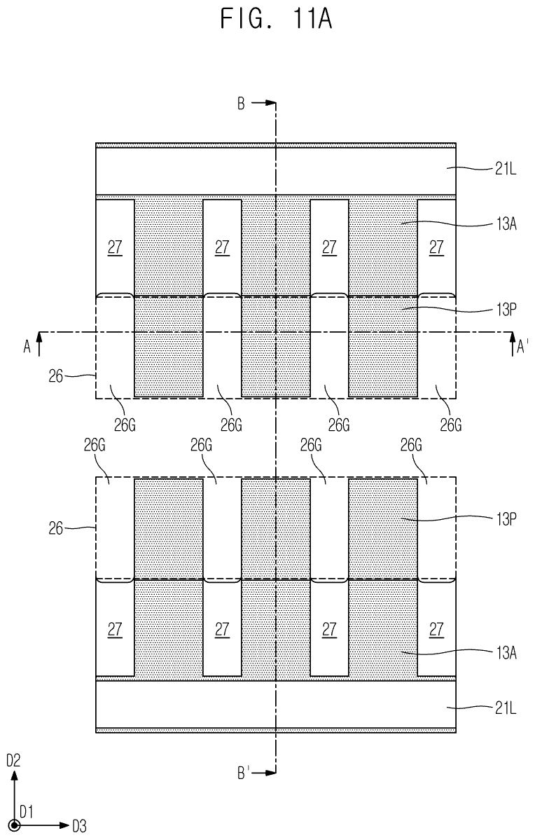

FIG. 9A is a plan view illustrating the structure at the second mold layer level for describing partial recessing of the second mold layers 13. FIG. 9B is a cross-sectional view illustrating the structure taken along line B-B′ of FIG. 9A.

As illustrated in FIGS. 9A and 9B, portions (first portions) of the second mold layers 13 may be recessed to form narrow sheets 13P. The wet etch process or dry etch process may be used to recess the second mold layers 13. Original body portions 13A and the narrow sheets 13P may be formed by the partial recessing of the second mold layers 13. The original body portions 13A may each maintain an original thickness T1, and the narrow sheets 13P may each have a thickness T2 less than the original thickness T1. Horizontal lengths of the original body portions 13A in the second direction D2 may be equal to or different from horizontal lengths of the narrow sheets 13P in the second direction D2. The combination of each original body portion 13A and each narrow sheet 13P may be a preliminary nano sheet 13′. The narrow sheets 13P may be referred to as “flat plate-shaped sheets”or “protruding narrow sheets”.

A recess process for forming the narrow sheets 13P may be referred to as a “thinning process” or “trimming process” of the second mold layers 13. In order to form the narrow sheets 13P, upper surfaces, lower surfaces and side surfaces of the second mold layers 13 may be recessed. The narrow sheets 13P may be referred to as “thin-body active layers”. The narrow sheets 13P may each include a monocrystalline silicon layer. The recess process for forming the narrow sheets 13P may use, for example, Hot SC-1 (HSC1). The HSC1 may include a solution in which ammonium hydroxide (NH₄OH), hydrogen peroxide (H₂O₂) and water (H₂O) are mixed in a ratio of 1:4:20. Using the HSC1, the second mold layers 13 may be selectively etched.

The narrow sheets 13P may be formed by the partial recess process for the second mold layers 13 as described above, and inter-nano sheet recesses 24 may be formed between the narrow sheets 13P that are vertically disposed. Upper and lower surfaces of the narrow sheets 13P may each include a flat surface. A boundary portion between each original body portion 13A and each narrow sheet 13P may be vertical or have a curvature. The first mold layers 12A may be disposed between the original body portions 13A that are vertically stacked. A horizontal arrangement of the narrow sheets 13P may be formed in the third direction D3. A vertical arrangement of the narrow sheets 13P may be formed in the first direction D1. The inter-nano sheet recesses 24 may be referred to as “vertical gaps” between the narrow sheets 13P having the vertical arrangement.

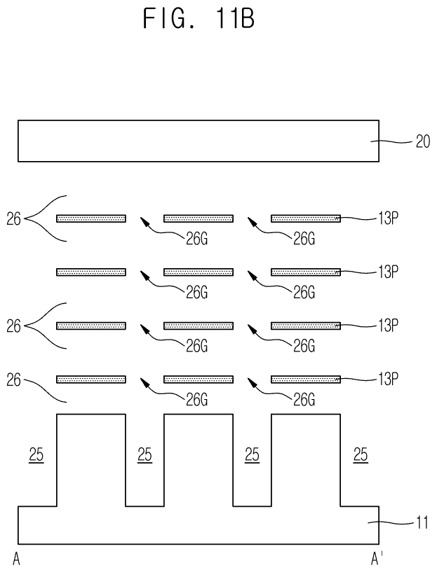

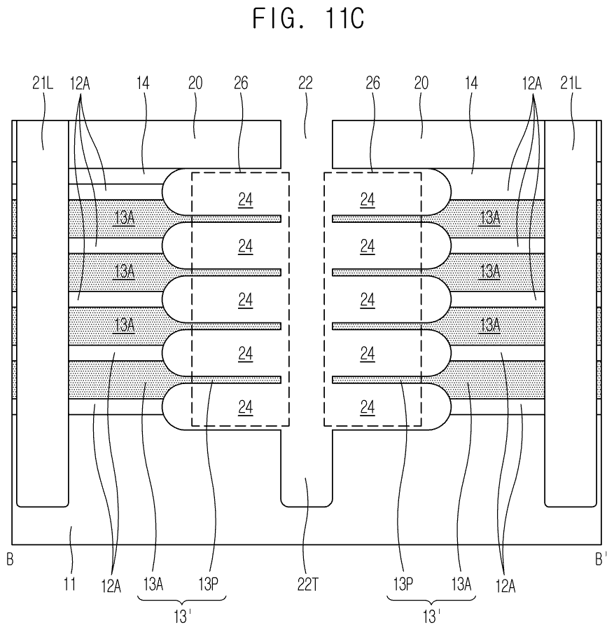

FIG. 10A is a plan view illustrating the structure at a narrow sheet level for describing a method for forming sacrificial isolation layer-level openings 25. FIG. 10B is a cross-sectional view illustrating the structure taken along line A-A′ of FIG. 10A. FIG. 10C is a cross-sectional view illustrating the structure taken along line B-B′ of FIG. 10A.

As illustrated in FIGS. 10A to 10C, the sacrificial isolation layers 18 may be selectively stripped through the first linear opening 22 and the inter-nano sheet recesses 24. Accordingly, the sacrificial isolation layer-level openings 25 may be formed between the original body portions 13A in the third direction D3.

Side surfaces of the first mold layers 12A, side surfaces of the original body portions 13A, and side surfaces of the narrow sheets 13P may be exposed in the third direction D3 by the sacrificial isolation layer-level openings 25.

In an embodiment, while the sacrificial isolation layer-level openings 25 are formed, a portion of the first hard mask layer 14 may be recessed. Accordingly, a space of an uppermost inter-nano sheet recess 24 may be expanded.

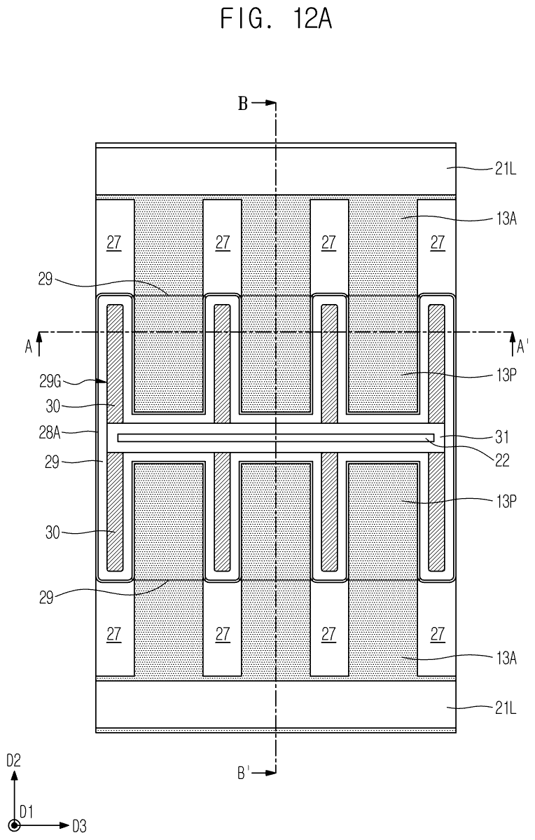

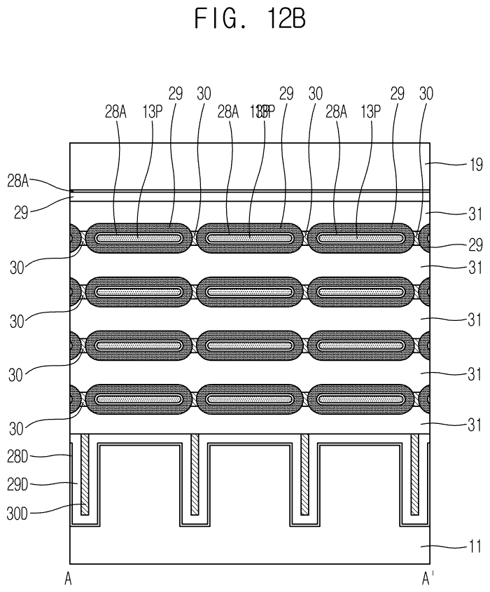

FIG. 11A is a plan view illustrating the structure at the narrow sheet level for describing a method for forming first inter-cell dielectric layers 27. FIG. 11B is a cross-sectional view illustrating the structure taken along line A-A′ of FIG. 11A. FIG. 11C is a cross-sectional view illustrating the structure taken along line B-B′ of FIG. 11A.

As illustrated in FIGS. 11A to 11C, the first inter-cell dielectric layers 27 may be formed in the sacrificial isolation layer-level openings 25. The first inter-cell dielectric layers 27 may each include a dielectric material. The first inter-cell dielectric layers 27 may each include silicon oxide, silicon nitride, silicon carbon oxide, or a combination thereof. Forming the first inter-cell dielectric layers 27 may include forming a dielectric material that fills the sacrificial isolation layer-level openings 25 and performing an etch-back process on the dielectric material. The etch-back process for forming the first inter-cell dielectric layers 27 may be performed in the second direction D2.

The first inter-cell dielectric layers 27 may fill portions of the sacrificial isolation layer-level openings 25. The side surfaces of the first mold layers 12A and the side surfaces of the original body portions 13A may be covered by the first inter-cell dielectric layers 27 in the third direction D3. The first inter-cell dielectric layers 27 may expose the side surfaces of the narrow sheets 13P. The other portions of the sacrificial isolation layer-level openings 25, i.e., non-gap-filled portions, may expose the side surfaces of the narrow sheets 13P.

After the first inter-cell dielectric layers 27 are formed, a nano sheet all-open recess 26 that opens all narrow sheets 13P may be formed. The nano sheet all-open recess 26 may expose all narrow sheets 13P in the third direction D3. For example, the nano sheet all-open recess 26 extending in the third direction D3 may surround all surfaces of the narrow sheets 13P at the same horizontal level.

The nano sheet all-open recess 26 may include a plurality of first gaps 26G, and the first gaps 26G may be included between the narrow sheets 13P in the third direction D3.

A horizontal arrangement of narrow sheets 13P may be formed in the third direction D3. A vertical arrangement of the narrow sheets 13P may be formed in the first direction D1. The first gaps 26G between the narrow sheets 13P may be referred to as horizontal gaps between the narrow sheets 13P having the horizontal arrangement.

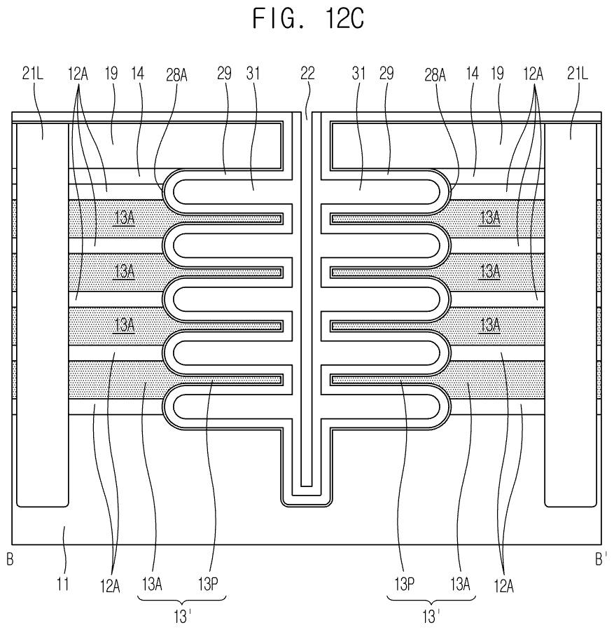

FIG. 12A is a plan view illustrating the structure at the narrow sheet level for describing a method for forming a second liner layer 29. FIG. 12B is a cross-sectional view illustrating the structure taken along line A-A′ of FIG. 12A. FIG. 12C is a cross-sectional view illustrating the structure taken along line B-B′ of FIG. 12A.

As illustrated in FIGS. 12A to 12C, a first liner layer 28A may be formed on exposed portions of the narrow sheets 13P. The first liner layer 28A may include silicon oxide, silicon nitride, metal oxide, metal oxide nitride, metal silicate, a high-k material, a ferroelectric material, an anti-ferroelectric material, or a combination thereof. The first liner layer 28A may include SiO₂, Si₃N₄, HfO₂, Al₂O₃, ZrO₂, AlON, HfON, HfSiO, HfSiON, or a combination thereof. The first liner layer 28A may be formed on all surfaces of the narrow sheets 13P. The first liner layer 28A may include first segments surrounding all surfaces of the narrow sheets 13P. The first liner layer 28A may further include second segments, and the second segments of the first liner layer 28A may be conformally formed on the surfaces of the original body portions 13A and the first mold layers 12A.

In an embodiment, the first liner layer 28A may be silicon oxide, and the silicon oxide may be formed by oxidizing the surfaces of the narrow sheets 13P. In an embodiment, the first liner layer 28A may be formed by a combination of a deposition process and an oxidation process of the silicon oxide.

The second liner layer 29 may be formed on the first liner layer 28A. The second liner layer 29 may include silicon nitride. The second liner layer 29 may surround and cover the narrow sheets 13P on the first liner layer 28A. The second liner layer 29 may be thicker than the first liner layer 28A. The second liner layer 29 may be referred to as a “surrounding target layer”. The second liner layer 29 may form second gaps 29G between the narrow sheets 13P in the third direction D3. The second liner layer 29 may have a small thickness that may form the second gaps 29G, and thus, the second liner layer 29 may have a seamless structure. The second liner layer 29 may include first segments surrounding the narrow sheets 13P on the first segments of the first liner layer 28A. The second liner layer 29 may further include second segments, and the second segments of the second liner layer 29 may be conformally formed on the second segments of the first liner layer 28A.

Gap-fill layers 30 may be formed on the second liner layer 29. The gap-fill layers 30 and the second liner layer 29 may be different materials. The gap-fill layers 30 may each include a material having a selectivity with respect to the first liner layer 28A and the second liner layer 29. The gap-fill layers 30 may each include a material having a selectivity with respect to nitride and oxide. The gap-fill layers 30 may each include polysilicon. In an embodiment, the gap-fill layers 30 may each include a metal-based material, such as titanium nitride, tungsten, or a combination thereof.

For example, the gap-fill layers 30 may be formed by a deposition process and an etch-back process of polysilicon. The second liner layer 29 may be interconnected by the gap-fill layers 30. The gap-fill layers 30 may fill the second gaps 29G of the second liner layer 29. The second liner layer 29 and the gap-fill layers 30 may fill the first gaps 26G between the nano sheets 13P disposed adjacent to each other. The second gaps 29G may be referred to as “narrow horizontal gaps” between the narrow sheets 13P having the horizontal arrangement. The first gaps 26G may be “first horizontal gaps”, and the second gaps 29G may be “second horizontal gaps”. Horizontal lengths of the first gaps 26G may be greater than horizontal lengths of the second gaps 29G.

Second inter-cell dielectric layers 31 may be formed on the gap-fill layers 30. The second inter-cell dielectric layers 31 may each include silicon oxide. The gap-fill layers 30 may each have a selectivity with respect to the second inter-cell dielectric layers 31.

As described above, the first segments of the second liner layer 29 and a plurality of gap-fill layers 30 may be alternately and repeatedly disposed in the third direction D3. The first segments of the second liner layer 29 and a plurality of second inter-cell dielectric layers 31 may be alternately and repeatedly stacked in the first direction D1. The plurality of gap-fill layers 30 and the second inter-cell dielectric layers 31 may be alternately and repeatedly stacked in the first direction D1. The first segments of the second liner layer 29 and the gap-fill layers 30 may be replaced by horizontal conductive lines during a subsequent process.

In an embodiment, the first segments of the second liner layers 29 disposed adjacent to each other may be prevented from being merged by the gap-fill layers 30.

As a comparative example, when the gap-fill layers 30 are omitted and a thickness of the second liner layer 29 increases, the first segments of the second liner layer 29 may be merged with each other. A seam or void may occur at a merged portion, and the seam or void may remain during a replacement process with the subsequent horizontal conductive lines. In an embodiment, since the gap-fill layers 30 are formed, the second liner layer 29 may be formed to have a small thickness, and thus the seam or void may be suppressed while the second liner layer 29 is formed.

As a comparative example, when the gap-fill layers 30 are omitted and the thickness of the second liner layer 29 increases, a space between the horizontal conductive lines disposed adjacent to each other may become narrower, thereby increasing the capacitance between the horizontal conductive lines. In an embodiment, since the second liner layer 29 may be formed to have a small thickness by the gap-fill layers 30, the space between the subsequent horizontal conductive lines may be secured sufficiently.

As described above, the second liner layer 29 according to an embodiment may have a small thickness without a seam. That is, the second liner layer 29 may be a seamless material.

While the first liner layer 28A, the second liner layer 29 and the gap-fill layers 30 are formed, a dummy first liner layer 28D, a dummy second liner layer 29D and dummy gap-fill layers 30D may be formed on the substrate 11.

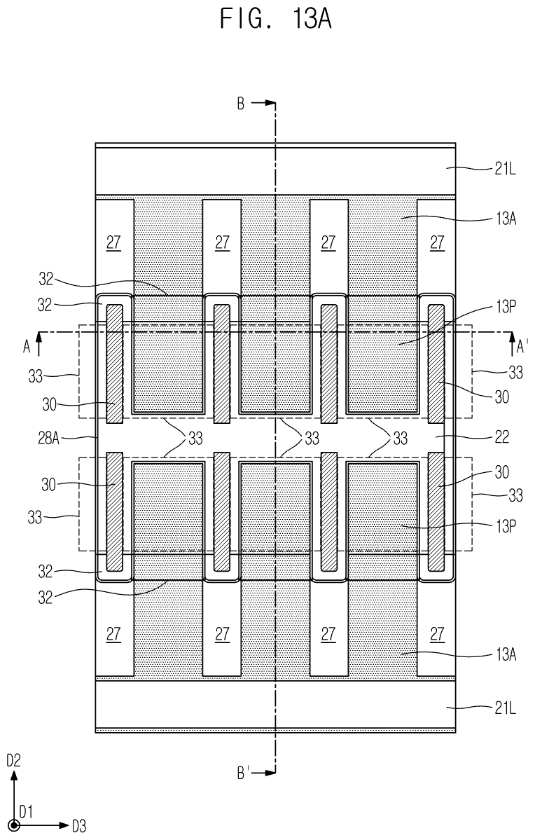

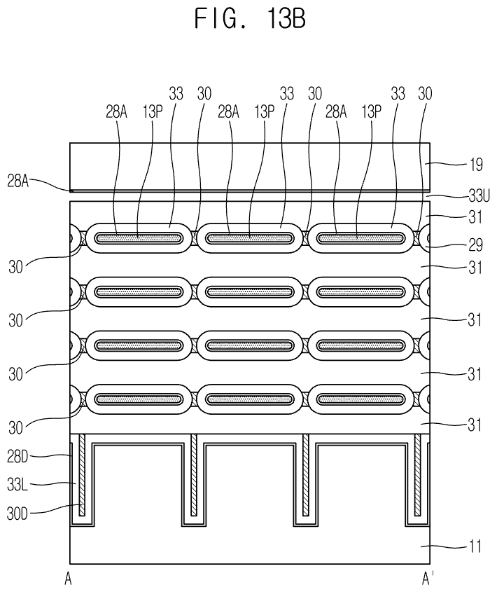

FIG. 13A is a plan view illustrating the structure at the narrow sheet level for describing a method for forming linear surrounding recesses 33. FIG. 13B is a cross-sectional view illustrating the structure taken along line A-A′ of FIG. 13A. FIG. 13C is a cross-sectional view illustrating the structure taken along line B-B′ of FIG. 13A.

As illustrated in FIGS. 13A to 13C, portions of the second inter-cell dielectric layers 31 may be cut in the second direction D2 through the first linear opening 22. Subsequently, the second liner layer 29 may be selectively recessed in the second direction D2. The second segments of the second liner layer may remain as indicated by reference numeral “32”. The dummy second liner layer 29D may be removed while the second liner layer 29 is recessed. The first liner layer 28A and the second liner layer 32 may form the first spacer SP1.

As the second liner layer 29 is selectively recessed, surrounding recesses 33 that surround the narrow sheets 13P of the preliminary nano sheets 13′ on the first liner layers 28A may be formed. The second inter-cell dielectric layers 31 may be disposed between the surrounding recesses 33 that are vertically disposed. An upper-level dummy horizontal recess 33U may be formed on an uppermost second inter-cell dielectric layer 31, and a lower-level dummy horizontal recess 33L may be formed below a lowermost second inter-cell dielectric layer 31. The upper-level and lower-level dummy horizontal recesses 33U and 33L may each have a non-surrounding shape, i.e., a flat shape. The lower-level dummy horizontal recess 33L may be a space where the dummy second liner layer 29D is removed. The second liner layers 32 may extend in the third direction D3 while surrounding the narrow sheets 13P at the same horizontal level. The narrow sheets 13P at the same horizontal level may refer to the narrow sheets 13P that are horizontally spaced apart in the third direction D3.

Since the second liner layer 29 is a seamless material, the second liner layer 29 may be uniformly recessed while the surrounding recesses 33, the lower-level dummy horizontal recess 33L and the upper-level dummy horizontal recess 33U are formed.

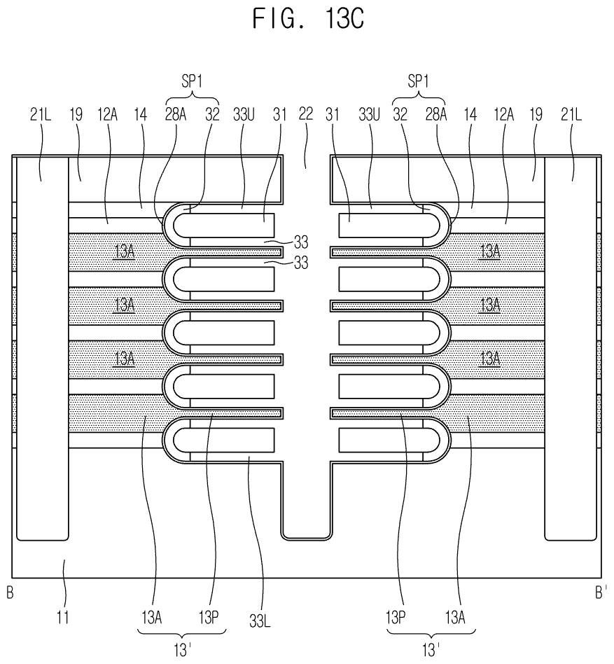

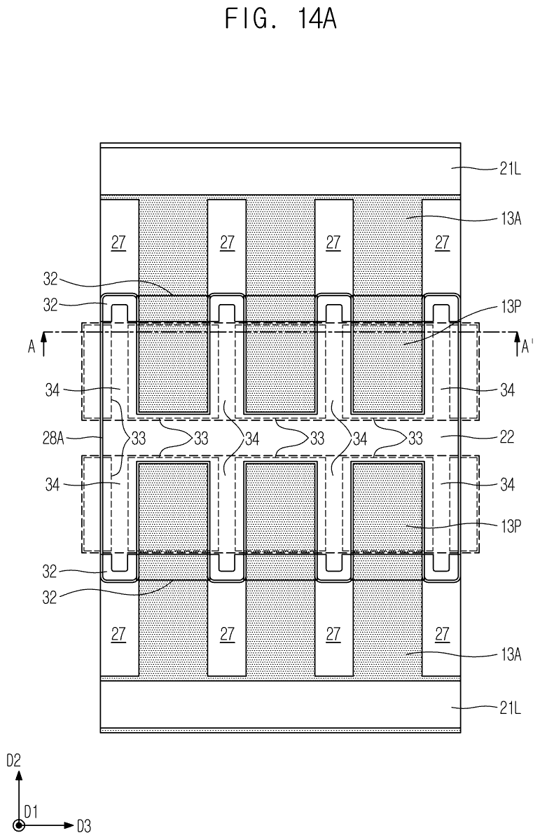

FIG. 14A is a plan view illustrating the structure at a nano sheet level for describing a method for forming bridge recesses 34. FIG. 14B is a cross-sectional view illustrating the structure taken along line A-A′ of FIG. 14A.

As illustrated in FIGS. 14A and 14B, the bridge recesses 34 may be formed between the surrounding recesses 33. To form the bridge recesses 34, the gap-fill layers 30 may be selectively removed in the second direction D2 through the first linear opening 22. While the gap-fill layers 30 are removed, the dummy gap-fill layers 30D may be removed. Since the dummy gap-fill layers 30D are removed, the size of the lower-level dummy horizontal recess 33L may be expanded.

The surrounding recesses 33 and the bridge recesses 34 may be interconnected.

After the surrounding recesses 33 and the bridge recesses 34 are formed, the first liner layers 28A and the second inter-cell dielectric layers 31 may be exposed.

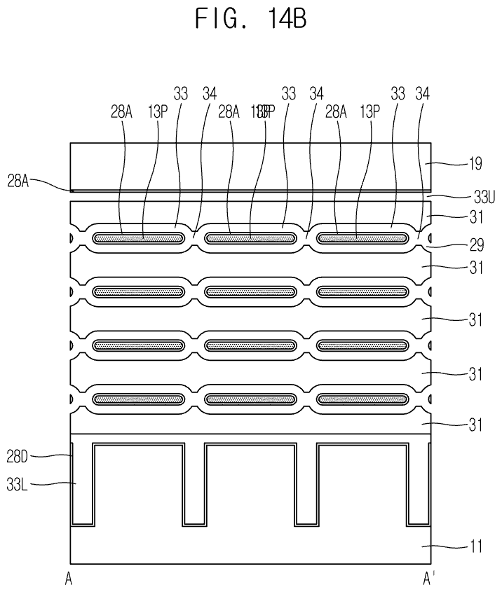

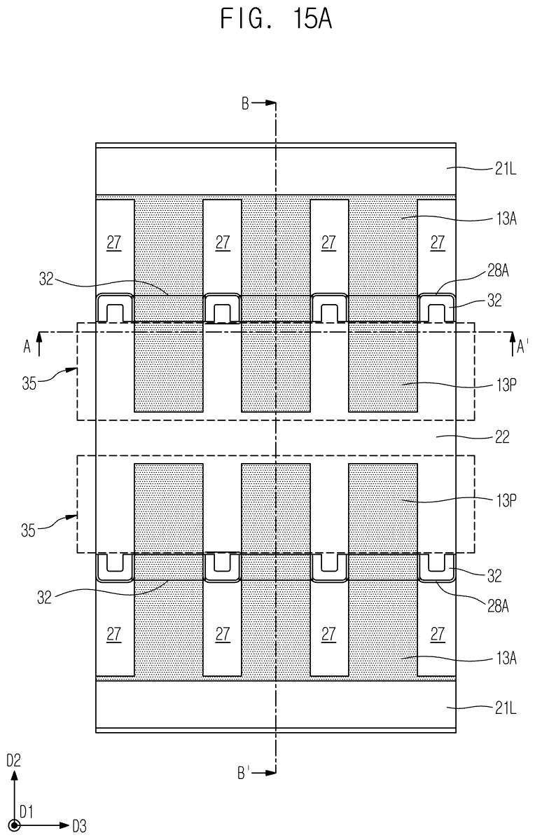

FIG. 15A is a plan view illustrating the structure at the nano sheet level for describing a method for forming linear surrounding recesses 35. FIG. 15B is a cross-sectional view illustrating the structure taken along line A-A′ of FIG. 15A. FIG. 15C is a cross-sectional view illustrating the structure taken along line B-B′ of FIG. 15A.

As illustrated in FIGS. 15A to 15C, the first segments of the first liner layer 28A exposed by the surrounding recesses 33 may be selectively removed to thus expose the surfaces of the narrow sheets 13P. While the first segments of the first liner layer 28A are selectively removed, the upper and lower surfaces of the second inter-cell dielectric layers 31 may be recessed. The second segments of the first liner layer 28A and the second liner layer 32 may form the first spacer SP1. As described with reference to FIG. 4B, the first liner layer 28A may correspond to the first liner S1, and the second liner layer 32 may correspond to the second liner S2. The first spacer SP1 may extend in the third direction D3 and surround the narrow sheets 13P at the same level in the third direction D3.

As described above, as a portion of the first liner layer 28A is removed, the linear surrounding recesses 35 may be formed to expose the surfaces of the narrow sheets 13 at the same horizontal level. The linear surrounding recesses 35 may include combinations of the surrounding recesses 33 and the bridge recesses 34.

The linear surrounding recesses 35 may extend lengthwise in the third direction D3 and simultaneously surround the narrow sheets 13P at the same level in the third direction D3. The second inter-cell dielectric layers 31 may be disposed between a plurality of linear surrounding recesses 35 in the first direction D1.

An extending lower-level dummy horizontal recess 33L may be formed in the substrate 11.

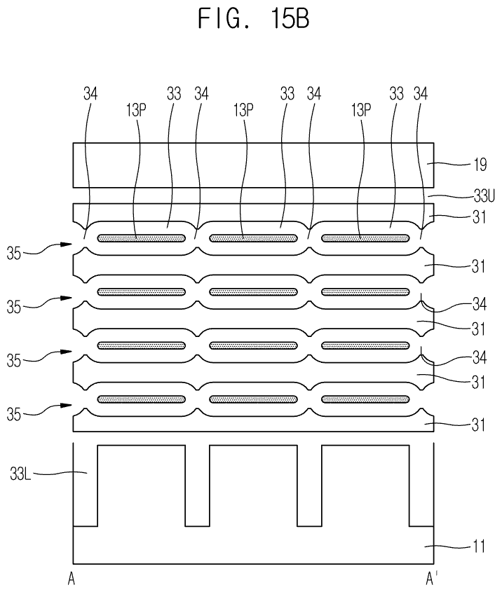

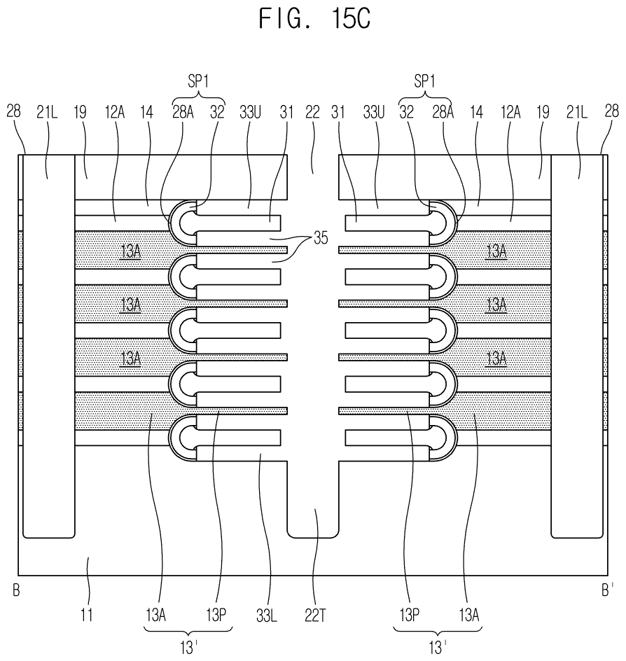

FIG. 16A is a plan view illustrating the structure at the narrow sheet level for describing a method for forming a nano sheet dielectric layer 28. FIG. 16B is a cross-sectional view illustrating the structure taken along line A-A′ of FIG. 16A. FIG. 16C is a cross-sectional view illustrating the structure taken along line B-B′ of FIG. 16A.

As illustrated in FIGS. 16A to 16C, the nano sheet dielectric layer 28 may be formed on exposed portions of the narrow sheets 13P. The nano sheet dielectric layer 28 may be formed by a deposition process of silicon oxide and an oxidation process of the narrow sheets 13P. When the nano sheet dielectric layer 28 is formed by a combination of the deposition process and the oxidation process, characteristics of the memory cell may be improved. In an embodiment, the nano sheet dielectric layer 28 may be formed by oxidizing the surfaces of the narrow sheets 13P. In an embodiment, the nano sheet dielectric layer 28 may include silicon oxide, silicon nitride, metal oxide, metal oxide nitride, metal silicate, a high-k material, a ferroelectric material, an anti-ferroelectric material, or a combination thereof. The nano sheet dielectric layer 28 may include SiO₂, Si₃N₄, HfO₂, Al₂O₃, ZrO₂, AlON, HfON, HfSiO, HfSiON, or a combination thereof. The nano sheet dielectric layer 28 may be formed on all surfaces of the narrow sheets 13P. The nano sheet dielectric layer 28 may also be formed on the surfaces of the second inter-cell dielectric layers 31, the surface of the lower-level dummy horizontal recess 33L, and the surface of the substrate 11.

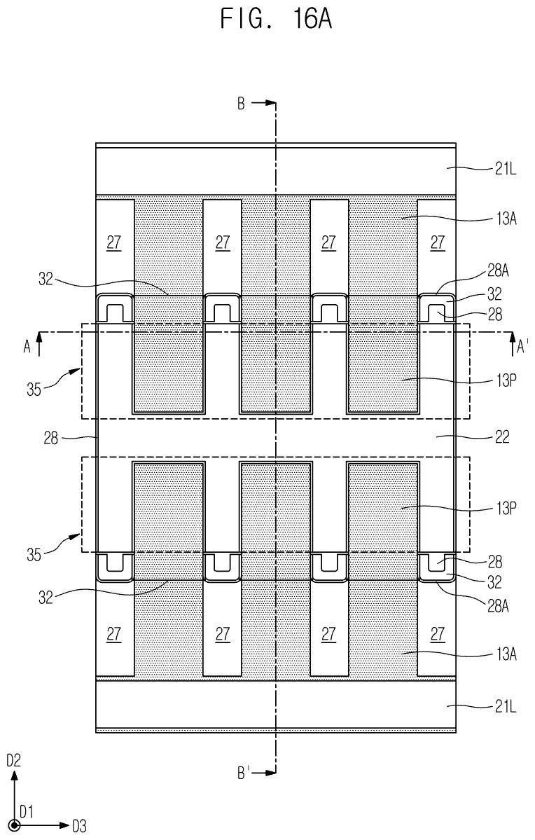

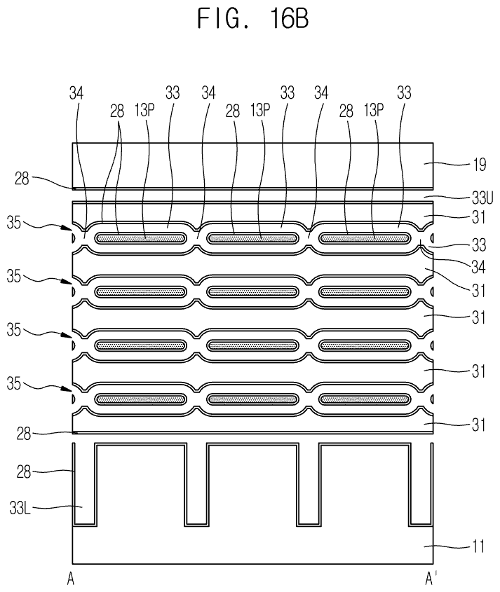

FIG. 17A is a plan view illustrating the structure at the narrow sheet level for describing a method for forming horizontal conductive lines 36. FIG. 17B is a cross-sectional view illustrating the structure taken along line A-A′ of FIG. 17A. FIG. 17C is a cross-sectional view illustrating the structure taken along line B-B′ of FIG. 17A.

As illustrated in FIGS. 17A to 17C, the horizontal conductive lines 36 filling the linear surrounding recesses 35 on the nano sheet dielectric layer 28 may be formed. The horizontal conductive lines 36 may horizontally extend in the third direction D3. The horizontal conductive lines 36 may correspond to the second conductive lines WL illustrated in FIG. 4B.

Forming the horizontal conductive lines 36 may include depositing a conductive material filling the linear surrounding recesses 35 on the nano sheet dielectric layer 28 and performing a horizontal etch-back process on the conductive material. Each of the horizontal conductive lines 36 may simultaneously surround the narrow sheets 13P at the same horizontal level. The narrow sheets 13P at the same horizontal level may refer to the narrow sheets 13P horizontally spaced apart from each other in the third direction D3. The horizontal conductive lines 36 may each include a metal-based material, a semiconductive material, or a combination thereof. The horizontal conductive lines 36 may each include molybdenum, molybdenum nitride, ruthenium, titanium nitride, tungsten, polysilicon, or a combination thereof. For example, the horizontal conductive lines 36 may each include a TiN/W stack in which titanium nitride and tungsten are sequentially stacked. The horizontal conductive lines 36 may each include an N-type work function material or a P-type work function material. The N-type work function material may have a low work function of approximately 4.5 eV or lower, and the P-type work function material may have a high work function of approximately 4.5 eV or higher. The second inter-cell dielectric layers 31 may be disposed between a plurality of horizontal conductive lines 36 in the first direction D1. The horizontal conductive lines 36 surrounding portions of the narrow sheets 13P may be referred to as “gate all around (GAA) electrodes”. The narrow sheets 13P may be referred to as “nano sheet channels”, “nano wires”or “nano wire channels”.

A lower-level dummy horizontal electrode 36L may be formed on the surface of the substrate 11, and an upper-level dummy horizontal electrode 36U may be formed over an uppermost horizontal conductive line 36. The lower-level and upper-level dummy horizontal electrodes 36L and 36U may each have a non-surrounding shape. The upper-level dummy horizontal electrode 36U and the lower-level dummy horizontal electrode 36L may correspond to the dummy second conductive lines WLU and WLL illustrated in FIG. 4B.

Each of the horizontal conductive lines 36 may include surrounding bodies 36S filling the surrounding recesses 33 and surrounding merged portions 36B filling the bridge recesses 34. The surrounding bodies 36S and the surrounding merged portions 36B may be alternately continuous to each other in the third direction D3. The surrounding bodies 36S may surround the narrow sheets 13P on the nano sheet dielectric layers 28. The surrounding merged portions 36B may interconnect the surrounding bodies 36S.

The horizontal conductive lines 36 may include inner surfaces facing the narrow sheets 13P and outer surfaces facing the second inter-cell dielectric layers 31. The inner surfaces of the horizontal conductive lines 36 may face the outer surfaces of the horizontal conductive lines 36. The nano sheet dielectric layers 28 may be disposed between the inner surfaces of the horizontal conductive lines 36 and the narrow sheets 13P. In addition, the nano sheet dielectric layers 28 may also be disposed on the outer surfaces of the horizontal conductive lines 36.

As described with reference to FIGS. 12A to 17C, the first segments of the second liner layer 29 may be replaced by the horizontal conductive lines 36, and the second segments of the second liner layer 29 may become a portion of the first spacer SP1. The horizontal conductive lines 36 and the first spacers SP1 may extend in the third direction D3. The horizontal conductive lines 36 and the first spacers SP1 may surround the narrow sheets 13P of the preliminary nano sheets 13′ disposed at the same horizontal level in the third direction D3.

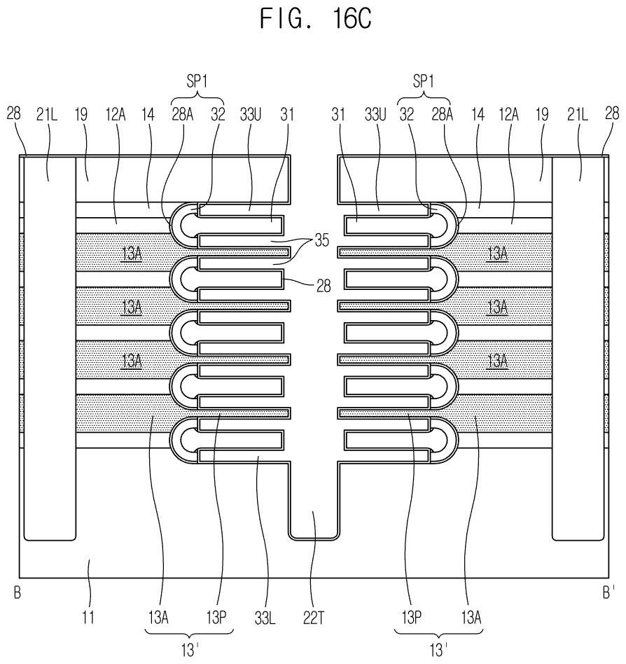

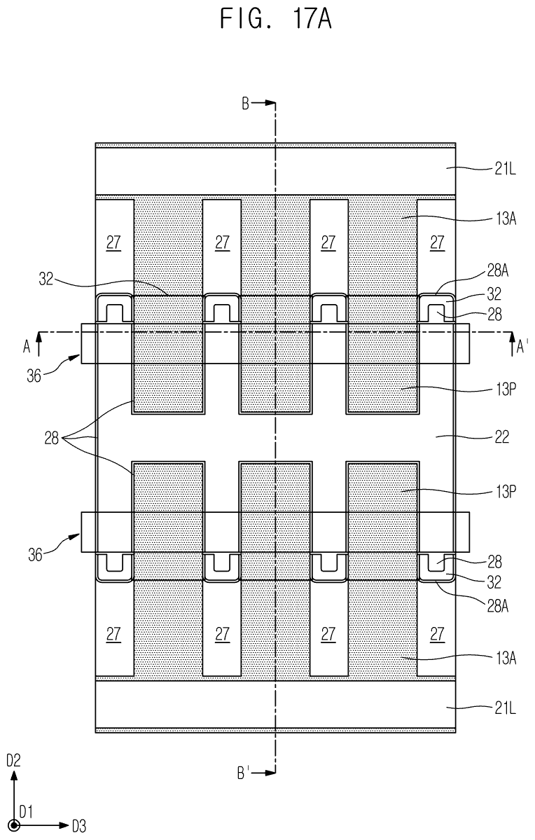

FIG. 18A is a plan view illustrating the structure at the narrow sheet level for describing a method for forming second spacers 37 and a vertical conductive line 38. FIG. 18B is a cross-sectional view illustrating the structure taken along line B-B′ of FIG. 18A.

As illustrated in FIGS. 18A and 18B, each of the second spacers 37 may be formed on one side of each of the horizontal conductive lines 36. The second spacer 37 may include silicon oxide, silicon nitride, silicon carbon oxide, an embedded air gap, or a combination thereof. Deposition and etch-back processes of a spacer material may be performed to form the second spacer 37. The second spacer 37 may include a stack of a silicon oxide liner and a silicon nitride liner. The second spacer 37 may correspond to the second spacer SP2 illustrated in FIG. 4B. In an embodiment, as described with reference to FIG. 4B, the second spacer 37 may include a stack of a third liner L3 and a fourth liner L4. The second spacer 37 may extend in the third direction D3 and surround the narrow sheets 13P at the same horizontal level in the third direction D3.

After the second spacer 37 is formed, a portion of the nano sheet dielectric layer 28 may be cut to expose one side of each of the narrow sheets 13P.

Subsequently, deposition and etch-back processes may be performed on a first bottom protective layer 37T. An upper surface of the first bottom protective layer 37T may be disposed at a lower level than a lowermost horizontal conductive line 36. The upper surface of the first bottom protective layer 37T may be at the same level or a lower level than an upper surface of the lower-level dummy horizontal electrode 36L.

The first bottom protective layer 37T may include a dielectric material. The first bottom protective layer 37T may include silicon oxide, silicon nitride, silicon carbon oxide, or a combination thereof.

Subsequently, the vertical conductive line 38 coupled in common to the narrow sheets 13P of the preliminary nano sheets 13′ may be formed. The vertical conductive line 38 may correspond to the first conductive line BL illustrated in FIG. 4B.

The vertical conductive line 38 may be coupled in common to the narrow sheets 13P disposed in the first direction D1. The vertical conductive line 38 may include a metal-based material. The vertical conductive line 38 may include titanium nitride, tungsten, or a combination thereof. In an embodiment, as described with reference to FIG. 4B, before the vertical conductive line 38 is formed, a first doped region DR, a first contact node BLC and an ohmic contact layer BLO may be formed.

Forming the vertical conductive line 38 may include performing deposition and etch processes of a vertical conductive line material. The second spacer 37 may be disposed between the vertical conductive lines 38 disposed adjacent to each other in the third direction D3. The vertical conductive lines 38 may vertically extend in the first direction D1. The vertical conductive lines 38 disposed adjacent to each other in the second direction D2 may be interconnected. That is, the narrow sheets 13P disposed adjacent to each other in the second direction D2 may share the vertical conductive line 38. The vertical conductive line 38 may have a U shape.

A supporter 39 or a supporter layer may be formed on the vertical conductive line 38. The supporter 39 may vertically extend in the first direction D1 and horizontally extend in the third direction D3. The vertical conductive lines 38 disposed adjacent to each other in the third direction D3 may be isolated by the supporter 39. The supporter 39 may include a dielectric material. The supporter 39 may include silicon oxide, silicon nitride, an air gap, or a combination thereof. The supporter 39 may be referred to as a “vertical dielectric layer”.

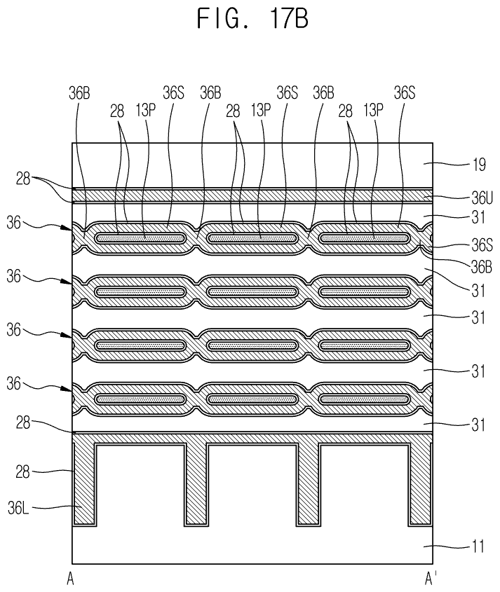

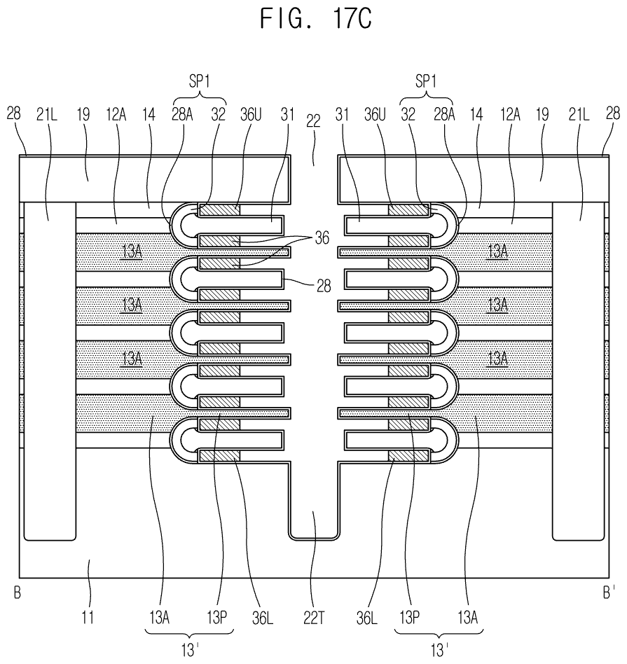

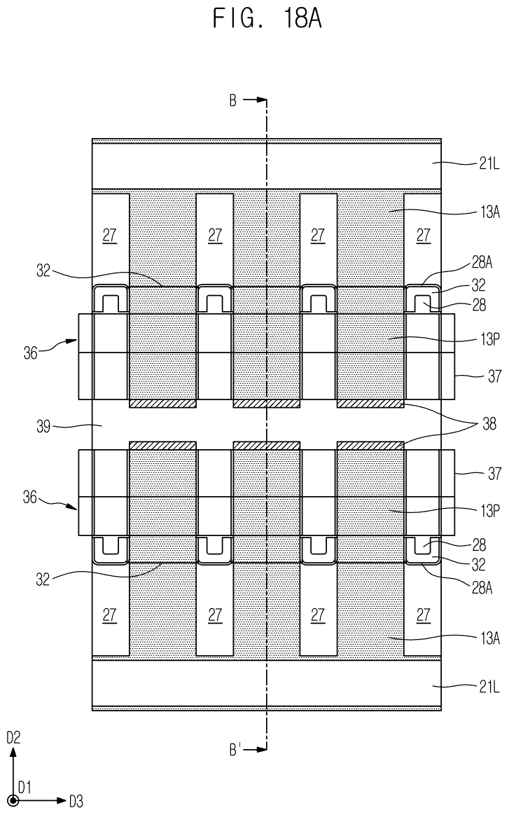

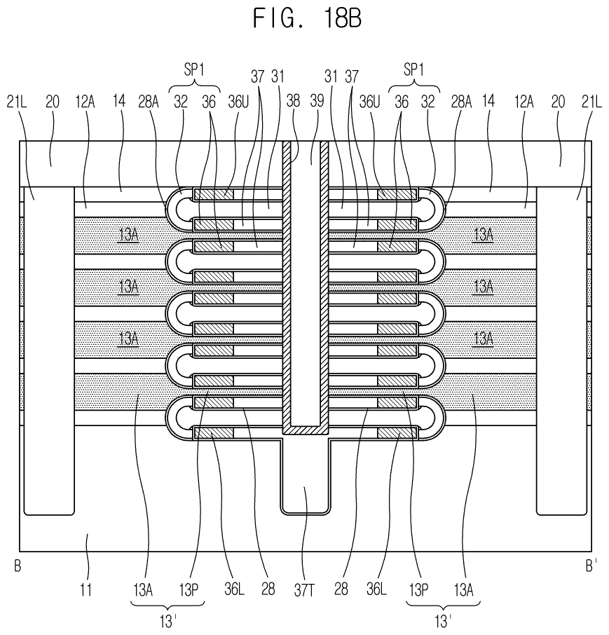

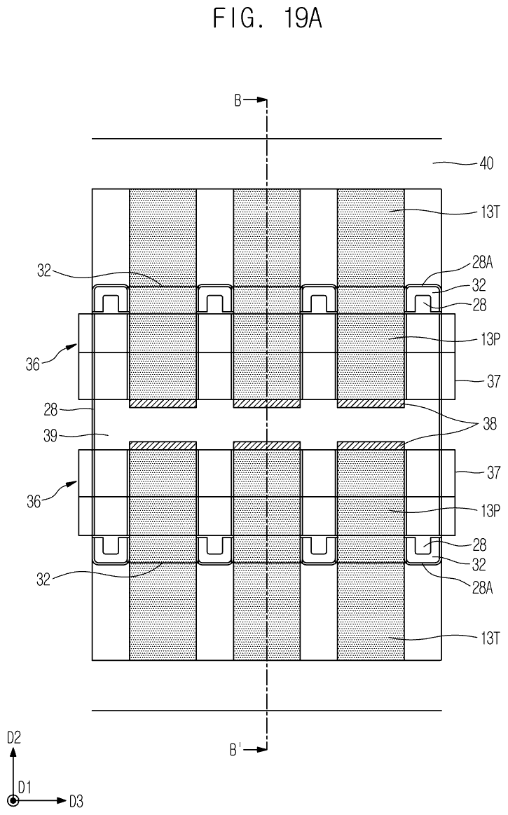

FIG. 19A is a plan view illustrating the structure at the nano sheet level for describing a method for forming second linear openings 40. FIG. 19B is a cross-sectional view illustrating the structure taken along line B-B′ of FIG. 19A.

As illustrated in FIGS. 19A and 19B, the second linear sacrificial layer 21L may be removed. Accordingly, the second linear openings 40 may be formed.

After the second linear openings 40 are formed, the first mold layers 12A may be selectively recessed through the second linear openings 40. In order to selectively recess the first mold layers 12A, a difference in etch selectivity between the first mold layers 12A and the original body portions 13A may be used. The first mold layers 12A may be removed using a wet etch process or a dry etch process. For example, when the first mold layers 12A include silicon germanium layers, and the original body portions 13A include monocrystalline silicon layers, the silicon germanium layers may be etched using an etchant or etch gas having a selectivity with respect to the monocrystalline silicon layers.

Subsequently, the original body portions 13A of the preliminary nano sheets 13′ may be recessed. To recess the original body portions 13A, the wet etch process or the dry etch process may be used. Vertical thicknesses of the original body portions 13A may be reduced, as indicated by reference numeral “13S”. Hereinafter, the original body portions having the reduced vertical thicknesses are referred to as “recessed body portions 13S”.

Inter-body recesses 41 may be formed between the recessed body portions 13S that are vertically disposed.

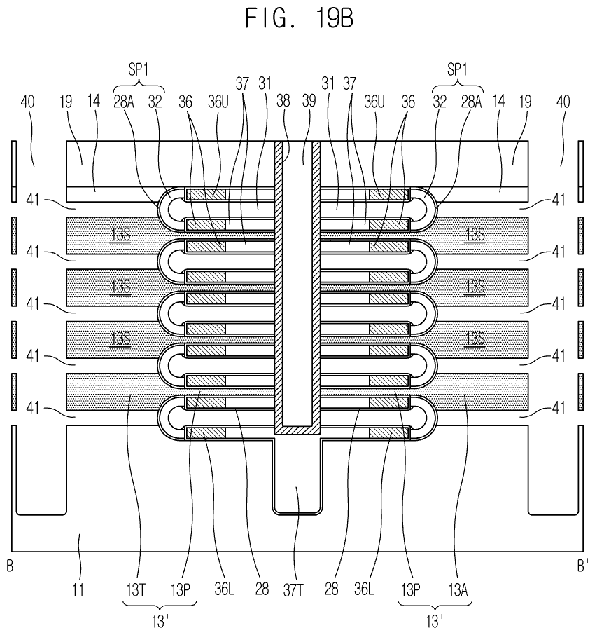

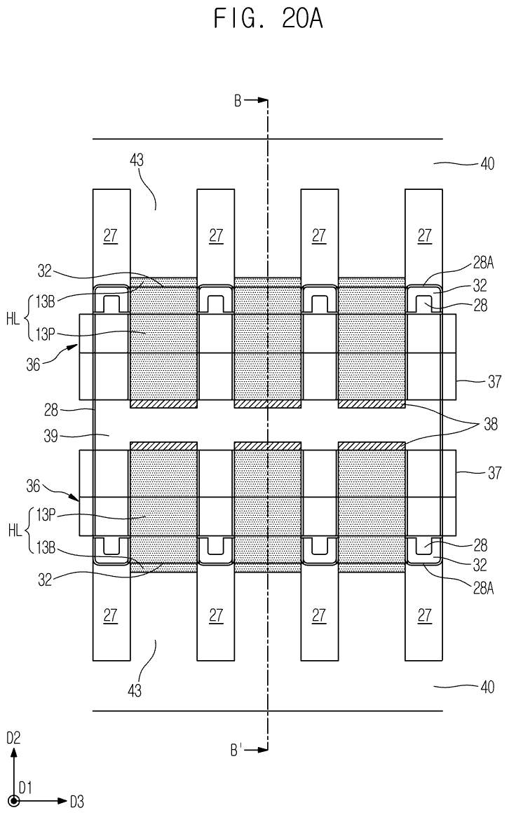

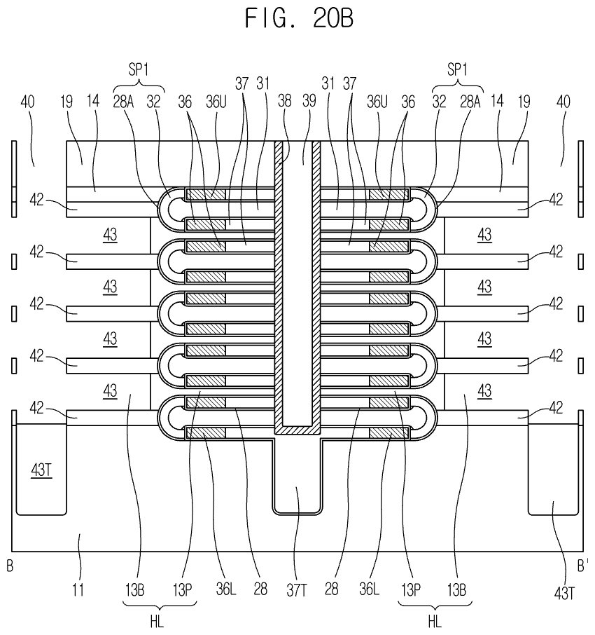

FIG. 20A is a plan view illustrating the structure at the narrow sheet level for describing a method for forming nano sheets HL. FIG. 20B is a cross-sectional view illustrating the structure taken along line B-B′ of FIG. 20A.

As illustrated in FIGS. 20A and 20B, third inter-cell dielectric layers 42 may be formed to fill the inter-body recesses 41. The third inter-cell dielectric layers 42 may each include silicon oxide.

After the third inter-cell dielectric layers 42 are formed, a second bottom protective layer 43T may be formed at a bottom portion of the second linear opening 40. The second bottom protective layer 43T may include a material having an etch selectivity with respect to the substrate 11. The second bottom protective layer 43T may include a dielectric material. The second bottom protective layer 43T may include silicon oxide, silicon nitride, silicon carbon oxide, or a combination thereof.

After the second bottom protective layer 43T is formed, storage openings 43 may be formed by horizontal recessing of the recessed body portions 13S. The storage openings 43 may be referred to as “data storage element openings”. The nano sheets HL may be formed by the horizontal recessing of the recessed body portions 13S. Each of the nano sheets HL may include a narrow sheet 13P and a wide sheet 13B. The wide sheet 13B of the nano sheet HL may refer to the recessed body portion 13S remaining after the recessing. An average vertical height of the wide sheets 13B of the nano sheets HL in the first direction D1 may be greater than an average vertical height of the narrow sheets 13P. Thicknesses of the wide sheets 13B of the nano sheets HL may gradually increase in the second direction D2. Horizontal lengths of the wide sheets 13B in the second direction D2 may be smaller than horizontal lengths of the narrow sheets 13P. The wide sheets 13B of the nano sheets HL may each have a fan-like shape. The wide sheets 13B may be referred to as “fan-shaped sheets”, and the narrow sheets 13P may be referred to as “flat plate-shaped sheets”.

The recessing process of the recessed body portions 13S to form the wide sheets 13B and the storage openings 43 may include an isotropic etch process or an anisotropic etch process. One side of each of the wide sheets 13B, i.e., the side exposed by each of the storage openings 43, may have a flat shape. The one side of the wide sheet 13B may have various shapes. For example, the one side of the wide sheet 13B may have a rounded concave shape, a rounded convex shape, an angled concave shape, or an angled convex shape.

The second bottom protective layer 43T and a lowermost second inter-cell dielectric layer 42 may prevent loss of the substrate 11 during the recessing process of the recessed body portions 13S.

Each of the nano sheets HL may include a first edge and a second edge. The first edge may refer to a portion electrically coupled to the vertical conductive line 38, and the second edge may refer to a portion exposed by each of the storage openings 43.

Each of the storage openings 43 may be disposed between the third inter-cell dielectric layers 42.

In an embodiment, the horizontal recessing of the recessed body portions 13S to form the wide sheets 13B may stop at a boundary area between the narrow sheet 13P and the wide sheet 13B.

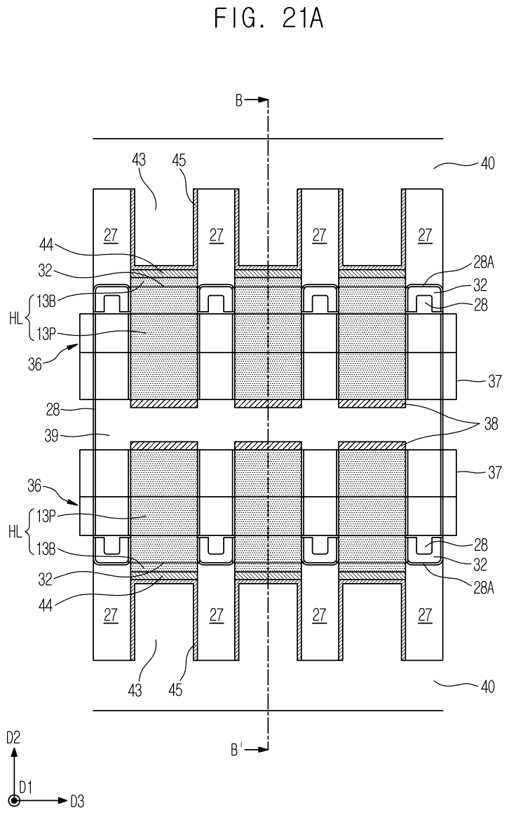

FIG. 21A is a plan view illustrating the structure at the nano sheet level for describing a method for forming contact nodes 44 and first electrodes 45. FIG. 21B is a cross-sectional view illustrating the structure taken along line B-B′ of FIG. 21A.

As illustrated in FIGS. 21A and 21B, a pre-cleaning process may be performed on one side of each of the nano sheets HL, that is, the surfaces of the wide sheets 13B.

Subsequently, the contact nodes 44 may be formed on one side of the nano sheets HL, that is, the wide sheets 13B of the nano sheets HL. Forming the contact nodes 44 may include selective epitaxial growth (SEG). For example, a semiconductive material may be grown from side surfaces of the wide sheets 13B through the selective epitaxial growth (SEG). The contact nodes 44 may each include SEG Si. Since the wide sheets 13B each include monocrystalline silicon, a silicon layer may be epitaxially grown along crystalline surfaces of the side surfaces of the wide sheets 13B.

The contact nodes 44 may each include a dopant. When the silicon layer is grown using the selective epitaxial growth (SEG), dopants may be doped in situ. Accordingly, the contact nodes 44 may each be a doped epitaxial layer. The contact nodes 44 may each include an N-type dopant as the dopant. The N-type dopant may include phosphorus, arsenic, antimony, or a combination thereof. The contact nodes 44 may include a phosphorus-doped silicon epitaxial layer formed by the selective epitaxial growth (SEG), i.e., a doped SEG SiP. In an embodiment, the contact nodes 44 may be formed by deposition and etch-back processes of doped polysilicon.

The contact nodes 44 may be disposed between the third inter-cell dielectric layers 42 vertically stacked. The contact nodes 44 may correspond to the second contact node SNC illustrated in FIG. 4B.

In an embodiment, second doped regions (refer to reference symbol “DR” of FIG. 1B) may be formed in the wide sheets 13B of the nano sheets HL. A heat treatment process may be performed to form the second doped regions, thereby allowing dopants to diffuse from the contact nodes 44.

In an embodiment, an ohmic contact layer including metal silicide may be further formed after the formation of the contact nodes 44.

Subsequently, the first electrodes 45 of the data storage elements may be formed on the contact nodes 44. The first electrodes 45 may each have a horizontally oriented cylindrical shape. The first electrodes 45 may be respectively disposed in the storage openings 43. The first electrodes 45 disposed adjacent to each other in the second direction D2 may be spaced apart from each other by the second linear openings 40. The first electrodes 45 disposed adjacent to each other in the third direction D3 may be spaced apart from each other by the first inter-cell dielectric layers 27. The first electrodes 45 disposed adjacent to each other in the first direction D1 may be spaced apart from each other by the third inter-cell dielectric layers 42. Forming the first electrodes 45 may include depositing a metal material, gap-filling a sacrificial material, and isolating the metal material in vertical and horizontal directions. The sacrificial material may include oxide or polysilicon.

Each of the first electrodes 45 may include an inner space and a plurality of outer surfaces. The inner space of the first electrode 45 may include a plurality of inner surfaces. The outer surfaces of the first electrode 45 may include a vertical outer surface and a plurality of horizontal outer surfaces. The vertical outer surface of the first electrode 45 may vertically extend in the first direction D1, and the horizontal outer surfaces of the first electrode 45 may horizontally extend in the second direction D2 or the third direction D3. The inner space of the first electrode 45 may be a three-dimensional space.

Among the outer surfaces of the first electrode 45, the vertical outer surface may be electrically coupled to the nano sheet HL and the second contact node 40.

The first electrode 45 may include metal, noble metal, metal nitride, conductive metal oxide, conductive noble metal oxide, metal carbide, metal silicide, or a combination thereof. For example, the first electrode 45 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, or a combination thereof.

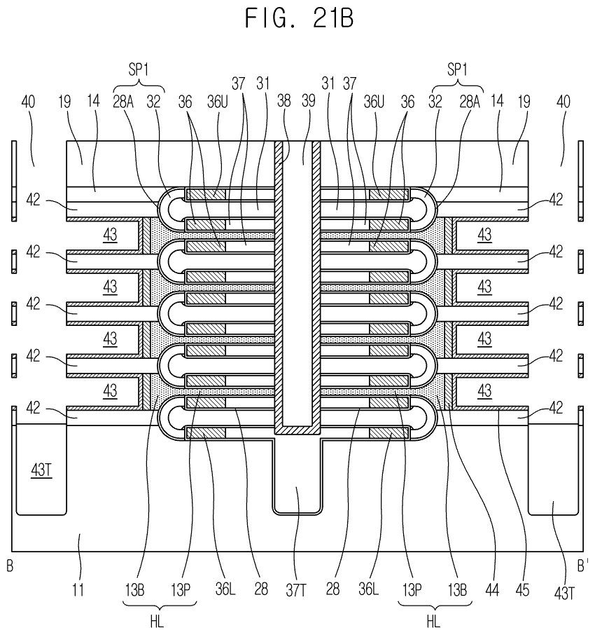

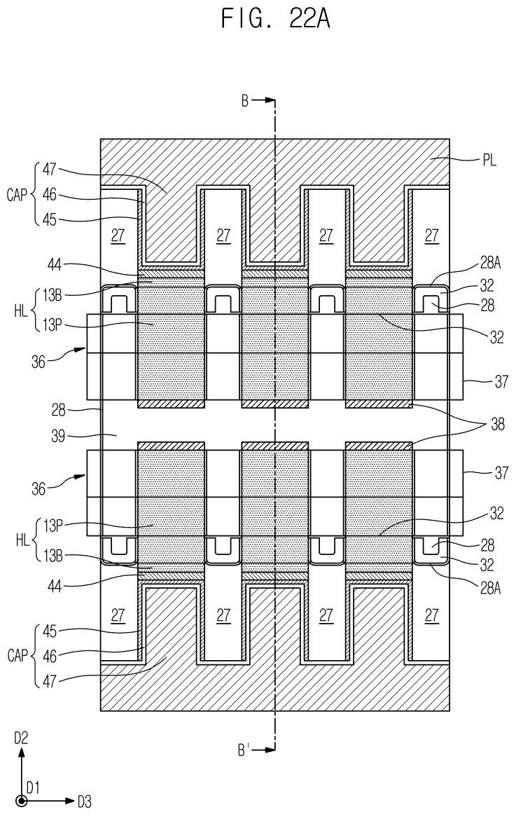

FIG. 22A is a plan view illustrating the structure at the nano sheet level for describing a method for forming second electrodes 47 of the data storage element. FIG. 22B is a cross-sectional view illustrating the structure taken along line B-B′ of FIG. 22A.

A dielectric layer 46 and the second electrode 47 may be sequentially formed on each of the first electrodes 45. The first electrode 45, the dielectric layer 46, and the second electrode 47 may be the data storage element CAP. The second electrodes 47 of the data storage elements CAP may be mutually merged and become a common plate PL.

The dielectric layer 46 may conformally cover the inner surfaces of the first electrode 45. The second electrode 47 may be disposed on the inner spaces of the first electrode 45 on the dielectric layer 46.

In an embodiment, as described with reference to FIG. 1B, the first electrode 45 may have a semi-cylindrical shape. The semi-cylindrical shape of the first electrode 45 may include cylindrical inner surfaces and semi-cylindrical outer surfaces. The dielectric layer 46 and the second electrode 47 may be disposed on the cylindrical inner surfaces of the first electrode 45. A portion of the dielectric layer 46 and a portion of the second electrode 47 may extend to be disposed on the semi-cylindrical outer surfaces of the first electrode 45. The second electrode 47 may vertically extend in the first direction D1.

The dielectric layer 46 may be referred to as a “capacitor dielectric layer” or a “memory layer”. The dielectric layer 46 may include silicon oxide, silicon nitride, a high-k material, a ferroelectric material, an antiferroelectric material, a perovskite material, or a combination thereof. The dielectric layer 46 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). The dielectric layer 46 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH(HfO₂/ZrO₂/Al₂O₃/ZrO₂/HfO₂) stack, a ZHZAZHZ(ZrO₂/HfO₂/ZrO₂/Al₂O₃/ZrO₂/HfO₂/ZrO₂) stack, a HZHZ(HfO₂/ZrO₂/HfO₂/ZrO₂) stack, or AHZAZHA(Al₂O₃/HfO₂/ZrO₂/Al₂O₃/ZrO₂/HfO₂/Al₂O₃) stack.

The second electrode 47 may include metal, noble metal, metal nitride, conductive metal oxide, conductive noble metal oxide, metal carbide, metal silicide, or a combination thereof. For example, the second electrode 47 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium silicon nitride/titanium nitride/tungsten (TiSiN/TiN/W) stack, or a combination thereof. The second electrode 47 may also include a combination of a metal-based material and a silicon-based material. For example, titanium nitride, tungsten and polysilicon may be sequentially stacked in the second electrode 47.

In an embodiment, an interface control layer may be further formed between the first electrode 45 and the dielectric layer 46 to alleviate leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 47 and the dielectric layer 46.

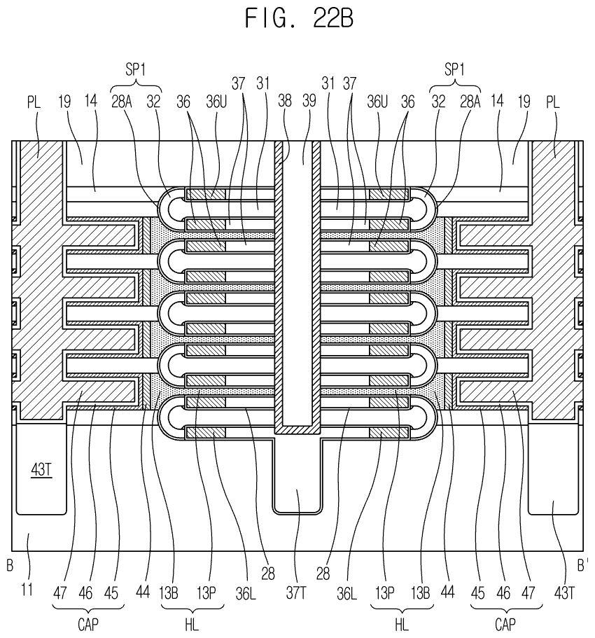

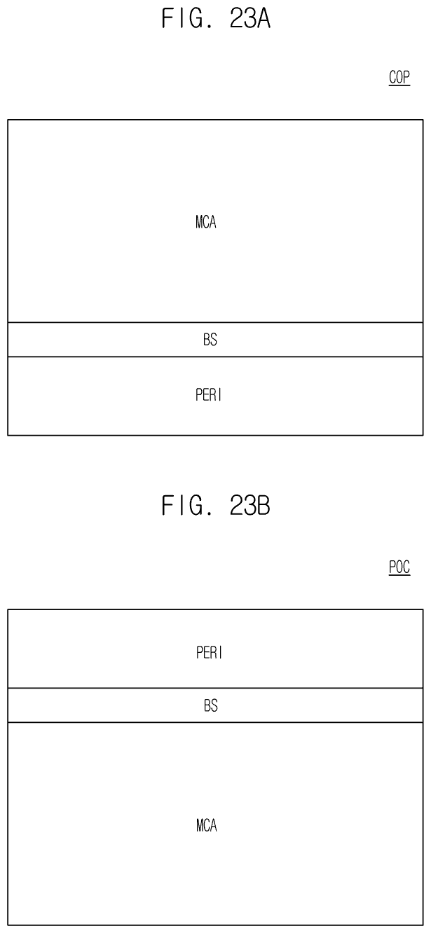

FIGS. 23A and 23B are schematic cross-sectional views illustrating a semiconductor device in accordance with an embodiment of the present disclosure.

As illustrated in FIG. 23A, a semiconductor device COP may include a memory cell array MCA, a peripheral circuit portion PERI, and a bonding interface BS. The bonding interface BS may be disposed between the memory cell array MCA and the peripheral circuit portion PERI. In the semiconductor device COP, the memory cell array MCA may be disposed at a higher level than the peripheral circuit portion PERI. The semiconductor device COP may be referred to as a “Peri Under Cell array (PUC) structure”. The memory cell array MCA may include a substrate on which back grinding is performed and an array of memory cells. For example, as described with reference to FIG. 22B, after the data storage element CAP is formed, the substrate 11 may be flipped over through a wafer flip, and then the substrate 11 may be partially ground back.

As illustrated in FIG. 23B, a semiconductor device POC may include a memory cell array MCA, a peripheral circuit portion PERI, and a bonding interface BS. The bonding interface BS may be disposed between the memory cell array MCA and the peripheral circuit portion PERI. In the semiconductor device POC, the memory cell array MCA may be disposed at a lower level than the peripheral circuit portion PERI. The semiconductor device POC may be referred to as a “Cell array Under Peri (CUP) structure”. Forming the peripheral circuit portion PERI may include forming a plurality of control circuits on a peripheral circuit substrate and forming multi-level interconnection on the control circuits.

In FIG. 23A and FIG. 23B, the bonding interface BS may include pad bonding, hybrid bonding, oxide-to-oxide bonding, metal-to-metal bonding, or a combination thereof. The hybrid bonding may refer to a combination of the pad bonding and the oxide-to-oxide bonding. The pad bonding may include forming a cell bonding pad for a memory cell array, forming a peripheral circuit bonding pad for a peripheral circuit portion, performing a wafer flip so that the cell bonding pad and the peripheral circuit bonding pad face each other, and performing wafer bonding.

The semiconductor device COP illustrated in FIG. 23A may perform the wafer flip on the substrate on which the memory cell array is formed so that the cell bonding pad and the peripheral circuit bonding pad face each other, after the cell bonding pad and the peripheral circuit bonding pad are formed. The semiconductor device POC illustrated in FIG. 23B may perform the wafer flip on the substrate on which the peripheral circuit portion is formed so that the cell bonding pad and the peripheral circuit bonding pad face each other, after the cell bonding pad and the peripheral circuit bonding pad are formed.

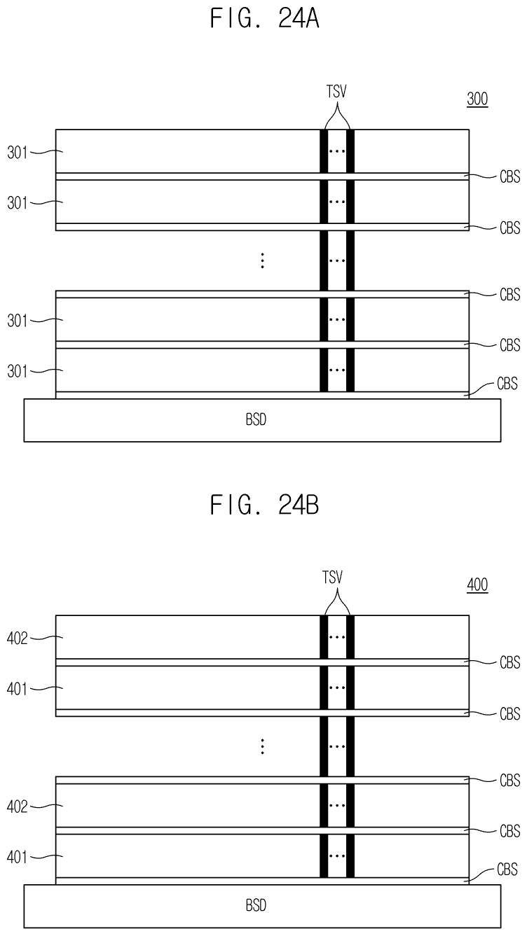

FIGS. 24A and 24B illustrate various views illustrating a stack assembly in accordance with an embodiment of the present disclosure.

As illustrated in FIG. 24A, a stack assembly 300 may include an assembly of semiconductor dies. For example, the stack assembly 300 may include a first semiconductor die BSD and a plurality of second semiconductor dies 301. The first semiconductor die BSD may include logic circuits. Each of the second semiconductor dies 301 may include memory cell arrays according to the embodiments described above. Each of the second semiconductor dies 301 may include structures in which a memory cell array and a peripheral circuit portion are stacked, for example, the semiconductor device COP illustrated in FIG. 23A or the semiconductor device POC illustrated in FIG. 23B. The logic circuits of the first semiconductor die BSD may be different from the peripheral circuit portions of the second semiconductor dies 301. The second semiconductor dies 301 may have chip levels or wafer levels.

The second semiconductor dies 301 may be electrically coupled to each other through a plurality of through silicon vias TSV and bonding interfaces CBS. The first semiconductor die BSD and a lowermost second semiconductor die 301 may be electrically coupled to each other through the bonding interface CBS. The second semiconductor dies 301 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

In an embodiment, the second semiconductor dies 301 may be wafer-flipped and ground back to form the bonding interfaces CBS.

As illustrated in FIG. 24B, a stack assembly 400 may include an assembly of semiconductor dies. For example, the stack assembly 400 may include a first semiconductor die BSD, and a plurality of alternating second and third semiconductor dies 401, and 402. The first semiconductor die BSD may include logic circuits. Each of the second semiconductor dies 401 and each of the third semiconductor dies 402 may include memory cell arrays according to the embodiments described above. The second semiconductor dies 401 and the third semiconductor dies 402 may have different structures.

Each of the second semiconductor dies 401 may include the semiconductor device COP illustrated in FIG. 23A in which a memory cell array is stacked over a peripheral circuit portion. Each of the third semiconductor dies 402 may include the semiconductor device POC illustrated in FIG. 23B in which a peripheral circuit portion is stacked over a memory cell array.

In an embodiment, each of the second semiconductor dies 401 may include the semiconductor device POC illustrated in FIG. 23B in which a peripheral circuit portion is stacked over a memory cell array, and each of the third semiconductor dies 402 may include the semiconductor device COP illustrated in FIG. 23A in which a memory cell array is stacked over a peripheral circuit portion.

The logic circuits of the first semiconductor die BSD may be different from the peripheral circuit portions of the second and third semiconductor dies 401 and 402. The second and third semiconductor dies 401 and 402 may have chip levels or wafer levels.

The second and third semiconductor dies 401 and 402 may be electrically coupled to each other through a plurality of through silicon vias TSV and bonding interfaces CBS. The first semiconductor die BSD and a lowermost second semiconductor die 401 may be electrically coupled to each other through the bonding interface CBS. The second and third semiconductor dies 401 and 402 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

In an embodiment, wafer-flip and back grinding may be performed to form the bonding interface CBS. For example, the second semiconductor dies 401 and/or the third semiconductor dies 402 may be wafer-flipped and ground back.

The stack assemblies 300 and 400 illustrated in FIGS. 24A and 24B may be high bandwidth memories.

According to various embodiments of the present disclosure, as a horizontal conductive line of a 3D memory cell is formed using a spacer layer and gap-fill layers, it is possible to prevent shorts between neighboring horizontal conductive lines.

According to various embodiments of the present disclosure, it is possible to improve reliability of a 3D memory device.

While the embodiments of the present disclosure has been illustrated and described with respect to specific embodiments and drawings, the disclosed embodiments are not intended to be restrictive. Further, it is noted that the embodiments of the present disclosure may be achieved in various ways through substitution, change, and modification, as those skilled in the art will recognize in light of the present disclosure, without departing from the scope of the present disclosure and the following claims. Furthermore, the embodiments may be combined to form additional embodiments.

What is claimed is:

1. A method for fabricating a semiconductor device, the method comprising:
forming a plurality of preliminary nano sheets disposed with first horizontal gaps therebetween over a substrate;
forming a spacer layer surrounding portions of the preliminary nano sheets and defining second horizontal gaps between the preliminary nano sheets;
forming gap-fill layers that fill the second horizontal gaps of the spacer layer;
forming inter-cell dielectric layers on the gap-fill layers and the spacer layer;
horizontally recessing the gap-fill layers and the spacer layer and forming a linear surrounding recess; and
forming a conductive line horizontally extending while surrounding portions of the preliminary nano sheets in the linear surrounding recess.

2. The method of claim 1, wherein the spacer layer and the gap-fill layers each include a seamless material.

3. The method of claim 1, wherein the spacer layer and the gap-fill layers include different materials.

4. The method of claim 1, wherein the spacer layer includes nitride, and the gap-fill layers each include polysilicon or a metal-based material.

5. The method of claim 1, wherein each of the preliminary nano sheets includes monocrystalline silicon, an oxide semiconductor material, or a two-dimensional material.

6. A method for fabricating a semiconductor device, the method comprising:
forming an alternating stack by alternately stacking a plurality of first mold layers with a plurality of second mold layers over a substrate;
forming a linear opening in the alternating stack;
recessing the first mold layers from the linear opening;
selectively recessing the second mold layers from the linear opening and forming narrow sheets of a plurality of preliminary nano sheets that are horizontally spaced apart from each other with first horizontal gaps therebetween;
forming a spacer layer that surrounds the narrow sheets of the preliminary nano sheets and defines second horizontal gaps;
forming gap-fill layers that fill the second horizontal gaps of the spacer layer;
forming inter-cell dielectric layers on the gap-fill layers and the spacer layer; and
replacing the gap-fill layers and portions of the spacer layer with a horizontal conductive line.

7. The method of claim 6, wherein each of the spacer layer and the gap-fill layers includes a seamless material.

8. The method of claim 6, wherein the spacer layer and the gap-fill layers include different materials.

9. The method of claim 6, wherein the spacer layer includes nitride, and each of the gap-fill layers includes polysilicon or a metal-based material.

10. The method of claim 6, wherein each of the second mold layers includes monocrystalline silicon, an oxide semiconductor material, or a two-dimensional material.

11. The method of claim 6, wherein each of the first mold layers of the alternating stack includes silicon germanium, and each of the second mold layers includes monocrystalline silicon.

12. The method of claim 6, wherein the first mold layers and the second mold layers are formed by epitaxial growth.

13. The method of claim 6, wherein replacing the gap-fill layers and the spacer layer with the horizontal conductive line includes:
forming linear surrounding recesses by removing the gap-fill layers and portions of the spacer layer; and
forming conductive materials horizontally extending while surrounding the narrow sheets of the preliminary nano sheets in the linear surrounding recesses.

14. The method of claim 6, further comprising:
after replacing the gap-fill layers and the spacer layer with the horizontal conductive line,
forming a vertical conductive line coupled to the narrow sheets of the preliminary nano sheets;
selectively recessing the other side of the preliminary nano sheets to form wide sheets that horizontally extend from the narrow sheets; and
forming data storage elements electrically coupled to the wide sheets, respectively.

15. A semiconductor device comprising:
a vertical stack in which inter-cell dielectric layers are alternately stacked with nano sheets;
first conductive lines coupled to first edges of the nano sheets and vertically oriented in a stacking direction of the vertical stack;
second conductive lines including inner surfaces that face the nano sheets and outer surfaces that face the inter-cell dielectric layers, and horizontally oriented in a direction crossing the stacking direction of the vertical stack;
nano sheet dielectric layers formed between inner surfaces of the second conductive lines and the nano sheets and formed between outer surfaces of the second conductive lines and the inter-cell dielectric layers; and
data storage elements coupled to second edges of the nano sheets, respectively.

16. The semiconductor device of claim 15, wherein each of the second conductive lines includes:
surrounding bodies that surround portions of the nano sheets; and
surrounding merged portions between the surrounding bodies.

17. The semiconductor device of claim 16, wherein the surrounding merged portions each include a seamless conductive material.

18. The semiconductor device of claim 16, wherein the surrounding bodies and the surrounding merged portions each include an integral structure of the same material.

19. The semiconductor device of claim 16, wherein the surrounding bodies and the surrounding merged portions each include a metal-based material.

20. The semiconductor device of claim 15, wherein the nano sheets each include a semiconductive material, an oxide semiconductor material, or a two-dimensional material.
